(19) United States
(12) Patent Application Publication
(10) Pub. No.: US 2026/0247693 A1
(43) Pub. Date: Aug. 20, 2026

(54) DEEP TRENCH CAPACITORS AND METHODS OF FORMING THE SAME

(71) Applicant: Taiwan Semiconductor Manufacturing Company, LTD., Hsinchu (TW)

(72) Inventors: Hsiang-Ting Cheng, Taoyuan (TW); Tao-Cheng Liu, Hsinchu (TW)

(21) Appl. No.: 19/054,999

(22) Filed: Feb. 17, 2025

(51) Int. Cl. H10D 84/80; H10D 1/00; H10D 1/66; H10D 30/01; H10D 30/67

(52) U.S. Cl. CPC H10D 84/813; H10D 1/047; H10D 1/665; H10D 30/0312; H10D 30/673

(57) ABSTRACT

A Deep Trench Capacitor (DTC) structure and method of forming the same including forming a transistor on an electrode within a DTC trench, the trench including alternating layers of a high K dielectric material and metal electrode material for functioning as a capacitor. The electrode transistor structure is formed to control electrical conductivity from the transistor gate to the connected metallic electrode layer of the DTC trench by the application of a gate voltage to switch on and off a capacitance provided by a first capacitor, i.e., first electrode(s) and high K dielectric pair, within the DTC trench. A DTC stacking structure provides the stacking and bonding of DTC wafers and dies by bonding electrical contact pairs or groups of each DTC wafer to provide a stacked DTC structure and/or device.

### BACKGROUND

The following relates to semiconductor integrated circuits (ICs) employing capacitive devices and/or structures, and to the manufacturing thereof.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross sectional view of an integrated circuit (IC) structure (Embodiment 1A) including a planar type tunable stacking structure for a deep trench capacitor (DTC) structure according to an example embodiment of the present disclosure, this embodiment including discrete DTC structures CapA1, CapB1 and CapC1 which each have trenches that extend from an intermetal dielectric region into the substate, each have planar electrode contact interfaces, and DTC structures CapB1 and CapC2 are tunable.

FIG. 1B is a top view of the IC structure shown in FIG. 1A (Embodiment 1A) according to an example embodiment of this disclosure.

FIG. 1C is a schematic representation of the IC shown in FIG. 1A (Embodiment 1A).

FIG. 1D is a cross sectional view of an integrated circuit (IC) structure (Embodiment 1B) including a planar type tunable stacking structure for a deep trench capacitor (DTC) structure according to an example embodiment of the present disclosure, this embodiment including discrete DTC structures CapA1, CapB1 and CapC1 where CapA1 and CapB1 DTC structures each have trenches that extend from an intermetal dielectric region into the substrate, CapC1 DTC structure has a relatively shallower trench only within the intermetal dielectric region, each of the DTC structures have planar electrode contact interfaces, and DTC structures CapB1 and CapC2 are tunable.

FIG. 1E is a cross sectional view of an integrated circuit (IC) structure (Embodiment 1C) including a planar type tunable stacking structure for a deep trench capacitor (DTC) structure according to an example embodiment of the present disclosure, this embodiment including discrete DTC structures CapA1, CapB1 and CapC1 where CapA1 and CapB1 DTC structures each have trenches that extend from an intermetal dielectric region into the substrate, CapC1 DTC structure has a relatively shallower trench only within the substrate, each of the DTC structures have planar electrode contact interfaces, and DTC structures CapB1 and CapC2 are tunable.

FIG. 2A is a cross sectional view of an integrated circuit (IC) structure (Embodiment 2A) including a 2.5D-like type tunable stacking structure for a deep trench capacitor (DTC) structure according to an example embodiment of the present disclosure, this embodiment including discrete DTC structures CapA2, CapB2 and CapC2, each including a stair shaped metal-insulator-metal (MIM) electrode contact interface extending into an intermetal dielectric region, where CapA2 and CapB2 DTC structures each have trenches only within the first substrate, and CapC2 DTC structure has a trench only within the second substrate, and DTC structure CapC2 is tunable to operatively/selectively connected to CapA2's outer capacitor electrode to increase the capacitance of the structure.

FIG. 2B is a cross sectional view of an integrated circuit (IC) structure (Embodiment 2B) including a 2.5D-like type tunable stacking structure for a deep trench capacitor (DTC) structure according to an example embodiment of the present disclosure, this embodiment including discrete DTC structures CapA2, CapB2 and CapC2 where CapA2 DTC structure has a trench that extend from a first intermetal dielectric region into a first substrate including a planar electrode contact interface, CapB2 DTC structure extends only into the first substrate including a planar electrode contact interface,, and CapC2 has a trench only within a second substrate including a stair shaped MIM electrode contact interface extending into a second intermetal dielectric region, and DTC structure CapC2 is tunable to operatively/selectively connected to CapA2's outer capacitor electrode to increase the capacitance of the structure.

FIG. 3A is a cross sectional view of an integrated circuit (IC) structure (Embodiment 3A) including a 3D-like type tunable stacking structure for a deep trench capacitor (DTC) structure according to an example embodiment of the present disclosure, this embodiment including discrete DTC structures CapA3 and CapB3, each including a stair shaped metal-insulator-metal (MIM) electrode contact interface extending into an intermetal dielectric region, where CapA3 DTC structure has dual trenches that extend only within a first substrate, CapB3 DTC structure has dual trenches that extend only within a second substrate, and DTC structure CapB3 is tunable to operatively/selectively connected to one of CapA2's capacitor electrodes to increase the capacitance of the structure.

FIG. 3B is a cross sectional view of an integrated circuit (IC) structure (Embodiment 3B) including a 3D-like type tunable stacking structure for a deep trench capacitor (DTC) structure according to an example embodiment of the present disclosure, this embodiment including discrete DTC structures CapA3, CapB3 and CapC3, each including a stair shaped metal-insulator-metal (MIM) electrode interface extending into an intermetal dielectric region, where CapA3 and CapB3 DTC structures each have trenches that extend only within a first substrate, CapC3 DTC structure has a trench that extends only within a second substrate, and CapB3 is tunable to operatively/selectively connect to one of CapA3's electrodes to increase the capacitance of the structure.

FIG. 3C is a cross sectional view of an integrated circuit (IC) structure (Embodiment 3C) including a 3D-like type tunable stacking structure for a deep trench capacitor (DTC) structure according to an example embodiment of the present disclosure, this embodiment including discrete DTC structures CapA3(1), CapA3(2), CapB3(1) and CapB3(2), each including planar electrode contact interfaces, where CapA3(1) and CapA3(2) DTC structures each have trenches that extend only within a first substrate, CapB3(1) and CapC3(2) DTC structure have trenches that extend only within a second substrate, CapB3(1) is tunable to operatively/selectively connect to one of CapA3(1)'s electrodes to increase the capacitance of the structure, and CapB3(2) is tunable to operatively/selectively connect to one of CapA3(2)'s electrodes to increase the capacitance of the structure.

FIGS. 4A-4N illustrates various fabrication stages associated with the fabrication of an IC structure (Embodiment 1A) according to an example embodiment of the present disclosure. FIG. 4A shows forming on a substrate a stop layer and intermetal dielectric layer; FIG. 4B shows the stage of etching a trench and depositing a trench liner; FIG. 4C shows the stage of depositing electrode and HK (High K) dielectric material, and depositing the fill dielectric material; FIG. 4D shows the stage of removing filled dielectric material, and polishing the electrode longitudinal ends and forming a BEOL (Back End of Line) transistor, e.g., thin film transistor (TFT) on a single electrode longitudinal end; FIG. 4E shows the next stage of depositing intermetal dielectric material on the trench structure and BEOL transistor; FIG. 4F shows the next stage of depositing an etch stop layer and subsequently depositing additional intermetal dielectric material; FIG. 4G shows the stage of forming electrical contacts to the trench electrodes and BEOL gate; FIG. 4H shows the stage of polishing the top surface, depositing additional intermetal dielectric material, and etching a second trench ; FIG. 4I shows the stage of forming the second trench electrodes, HK layers between the electrodes, and filling the second trench core with a dielectric filler material; FIG. 4J shows the stage of forming contacts to the first trench and patterning a metallization layer M1 and etch stop layer ; FIG. 4K shows the stage of polishing the etch stop layer, depositing additional intermetal dielectric material and forming another etch stop layer; FIG. 4L shows the formation of contacts to the second trench electrodes ; FIG. 4M shows the formation of vias V1 electrically connected to the patterned metallization layer M1 ; and FIG. 4N shows the completed structure after forming another patterned metallization layer M(2 to N) electrically connected to the first trench vias V1 and second trench contacts.

FIGS. 5A-5F illustrates various fabrication stages associated with the fabrication of an IC structure (Embodiment 2A) according to an example embodiment of the present disclosure. FIG. 5A shows forming on a substrate a trench line layer and intermetal dielectric layer ; FIG. 5B shows the stage of etching a first and second trench and depositing additional liner material in the trenches; FIG. 5C shows the stage of depositing electrode and HK (High K) dielectric material in both the first and second trenches, and depositing fill dielectric material in the first and second trenches; FIG. 5D shows the stage of removing filled dielectric material, depositing an etch stop layer, depositing additional intermetal dielectric material, performing a patterning photoresist lithographic process (4 times) to form the electrode step structure shown, forming the electrode metal contacts and polishing the electrode contacts; FIG. 5E shows the next stage including the bonding of a second DTC structure formed similarly, where the polished metal contacts are bonded to stack the first and second DTC structures; and FIG. 5F shows a final stage of the fabrication process including polishing the structure to expose the electrode metal contacts of the second DTC structure, forming an etch stop layer, depositing additional intermetal dielectric material, forming the metal contacts electrically connected to the second DTC structure electrodes and performing a patterned deposition process to form the metallization circuit layer M1.

FIGS. 6A-6D illustrates various fabrication stages associated with the fabrication of an IC structure (Embodiment 3A) according to an example embodiment of the present disclosure. FIG. 6A shows an initial stage of 2 DTC wafers after polishing (only one shown); FIG. 6B shows the bonding of the wafers by bonding of the metal contacts of each of the wafers; FIG. 6C shows the stage of polishing the structure to expose the electrodes of one of the wafers, depositing intermetal dielectric material, forming metal contacts to the electrodes of a top wafer trench, and subsequently depositing intermetal dielectric material and patterned metallization layer circuits, as well as a passivation layer, the metal contacts and metallization layer circuit providing electrical connections of the resulting DTC 3D stacked structure on a first side, and FIG. 6D shows, similar to FIG. 6C, the stage of polishing the structure to expose the electrodes of one of the wafers, depositing intermetal dielectric material, forming metal contacts to the electrodes of a top wafer trench, and subsequently depositing intermetal dielectric material and patterned metallization layer circuits, as well as a passivation layer, the metal contacts and metallization layer circuit providing electrical connections of the resulting DTC 3D stacked structure on a second side.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Numerical values in the specification and claims of this application should be understood to include numerical values which are the same when reduced to the same number of significant figures and numerical values which differ from the stated value by less than the experimental error of measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer,” as used herein, may include a single layers or multiple layers.

The term “conductive feature,” as may be used herein refers to a metallization layer contact, patterned metallization layer contact, or other electrical metal contact.

The term “intermetal dielectric” (IMD) film or layer, as may be used herein, refers to a dielectric/insulation material(s) layer between two metal layers.

The term “interlayer dielectric” (ILD) layer, as may be used herein, refers to an insulating structure of material(s) placed between two conductive layers.

The term “line” and “metal line,” as may be used herein, is a conductive path that is created during the back end of line (BEOL) process and transmits electrical signals through a semiconductor chip's circuit pattern.

The term “stacked” and “vertically stacked” as used herein, refers to the stacking or forming of a two or more transistor structures where a first and second transistor are substantially arranged or formed in an elongated pattern in contrast to a planar structure that includes a side-by-side arrangement of two or more transistor structures. The term “vertical” or “vertically” is not relative to gravity and can include a lateral layout where a first transistor is laterally stacked and formed adjacent to a second lateral transistor with structures as disclosed herein.

Some embodiments disclosed herein relate to semiconductor devices, including stacked capacitance device structures and methods of forming the same. Specifically, this disclosure provides Deep Trench Capacitor (DTC) structures, DTC devices, and DTC Integrated Circuits (IC) having multiple trench depths and/or DTC structure types integrated and fabricated into a silicon substrate and/or dielectric region that provide a tunable/adjustable or variable capacitance performance of the resulting structure, device and/or IC. Furthermore, the tunable capacitor structure enables the precise control of the capacitance of a resulting DTC structure for integration with other IC circuit devices or structures, etc., required to satisfy the specific functional requirements of a resulting IC or device.

Additional embodiments disclosed herein, include the use of a wafer and/or die stacking arrangement where the bonding of the semiconductor wafers is accomplished through the bonding of electrical contacts electrically connected to DTC electrodes of first and second wafers, at a wafer bonding boundary, to bond the first and second wafers (e.g., bottom wafer and top wafer) and provided a completed DTC structure which includes the selective use of one or more capacitor structures of each of the wafers, depending on a selection of the electrode contacts used for the wafer bonding process. In other words, as will be further described below, this disclosure provides configurable DTC structures that use the wafer bonding process to selectively provide DTC structures of a selectable or configurable capacitance in a single or common device, thereby providing a diverse stacking structures (e.g., planar/2.5D/3D) enabling the versatile application of DTCs in 3DICs.

Deep trench capacitors (DTCs) are semiconductor devices that can be used to add capacitance to various integrated circuits. One advantage of using DTCs is that DTCs can be packed at high densities and provide higher capacitance per unit area over other capacitance devices. DTCs are applied in various IC applications, such as networking, communications, optical communications, medical devices, and automotive electronics.

According to some embodiments, the DTC structures are formed in a one or more silicon substrates and/or intermetal dielectric bilayers or dual layers, where the DTC structures (i.e., wafers or dies) are bonded with electrode contact holes. A back end of the line (BEOL) formed transistor, e.g., IGZO thin film transistor (TFT) is formed one or more electrodes associated with, respectively, one or more capacitors of a DTC to provide the tunable function of the DTC structure. Specifically, the BEOL transistor functions to effectively turn ON and OFF the electrical conductivity path from a voltage source applied to the DTC device to an electrode/electrode layer within the trench of the DTC structure, the switched electrode operatively associated with a dielectric layer used for storing a portion of the electrical charge capacitance of the device. In other words, by switching ON and OFF the BEOL transistor, the capacitance of the underlying DTC structure can be tuned or adjusted, where switching ON the BEOL transistor provides a relatively higher capacitance and switching OFF the BEOL transistor provides a relatively lower capacitance of the device.

Furthermore, DTC stacked structure sand methods of forming the same are disclosed where (1) the DTC stacked structure, or device, provides different capacitances simultaneously within a single DTC or IC product; (2) the disclosed DTC structure is expandable horizontally and vertically, offering a relatively larger surface area to increase capacitance. ; and (3) a disclosed 3D IC structure allows circuits to connect two sides or both sides of a stacked wafer structure, providing a versatile three-dimensional structural application. In addition, incorporating the adjustable BEOL capacitor disclosed herein to the DTC stacked structure allows for precise adjustments of the required capacitance in DTC products without needing structural modifications.

According to some embodiments, The DTC trenches are 1) located completely within a substrate, 2) located within the intermetal dielectric, or 3) located in both the substrate and intermetal dielectric layer. These DTC structure locations provide flexibility to allow for different device designs and can also reduce the DTC trench depth within the substrate, thereby minimizing the risk of wafer breakage. Additionally, having the DTC trench solely within the intermetal dielectric can reduce the complexity of the insulation layer process, i.e. directly depositing the electrode/HK layers.

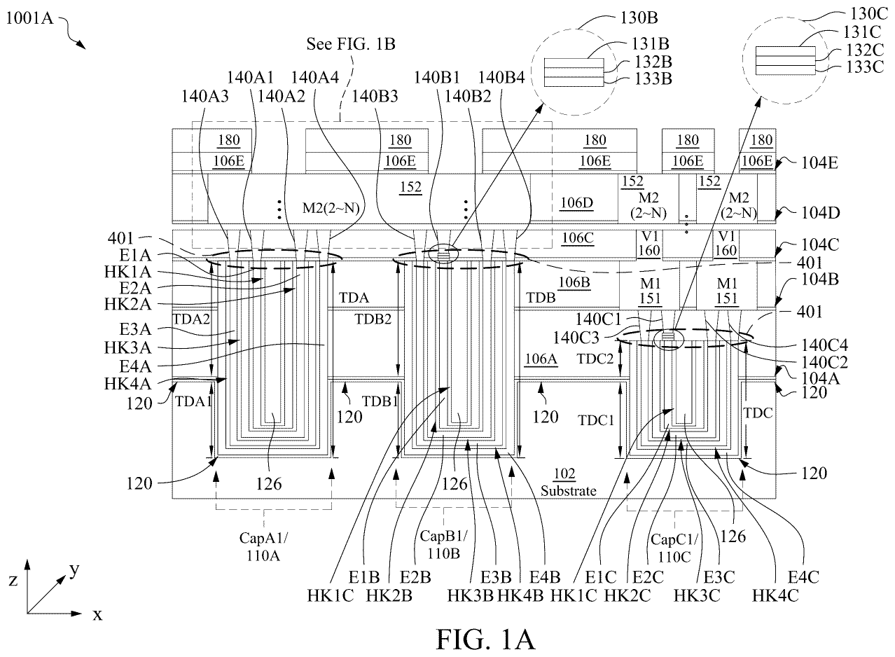

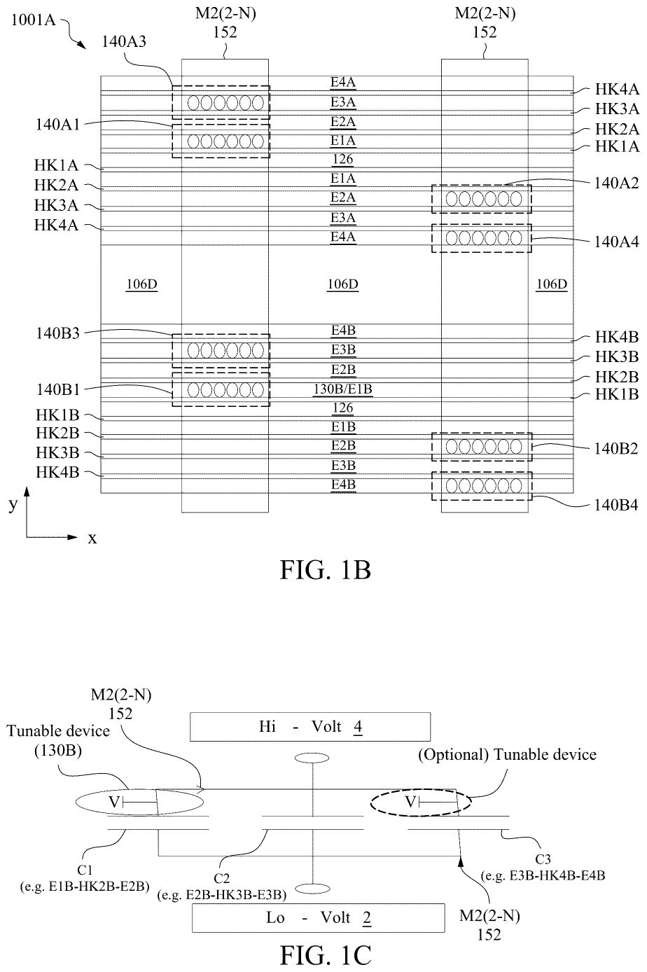

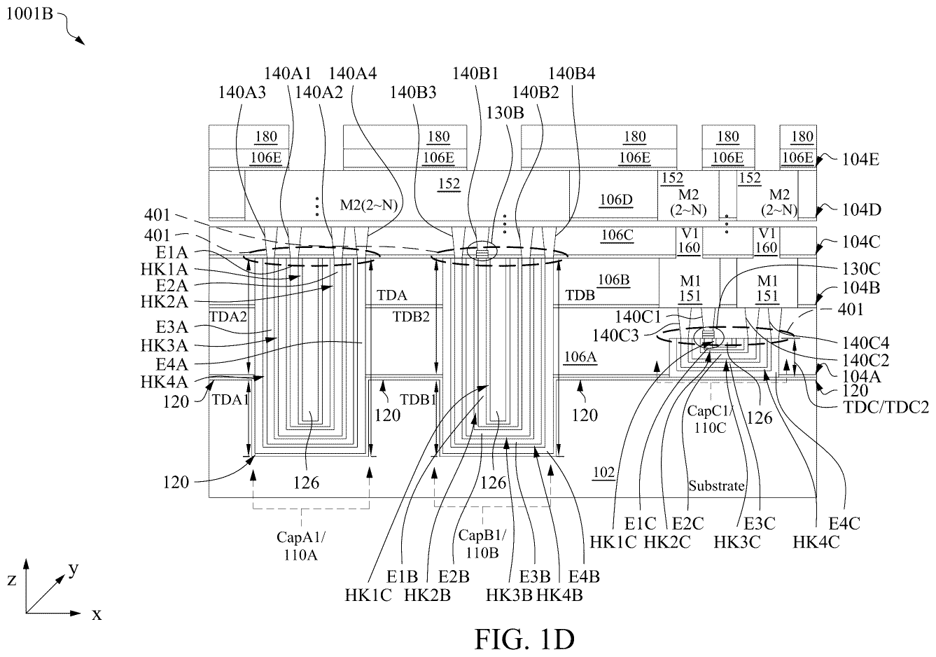

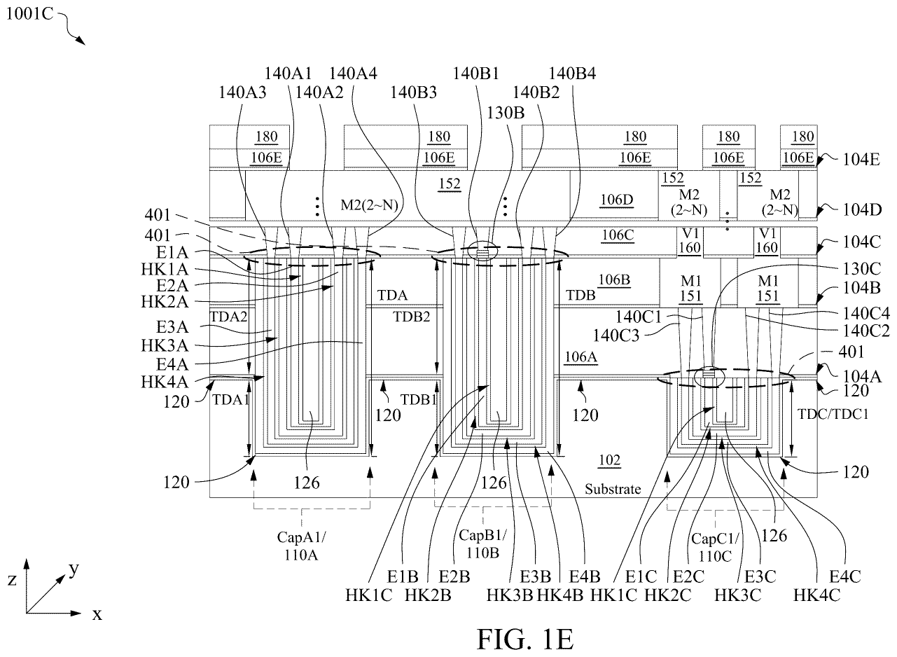

With reference to FIG. 1A, shown is a cross sectional view of an integrated circuit (IC) structure (Embodiment 1A) including a planar type tunable stacking structure for a deep trench capacitor (DTC) structure according to an example embodiment 1001A of the present disclosure, this embodiment including discrete DTC structures CapA1, CapB1 and CapC1 which each have trenches 110A, 110B and 110C, respectively, that extend from intermetal dielectric regions 106A and/or 106B into the substate. Each of the DTC structures has a planar electrode contact interface, and DTC structures CapB1 and CapC2 are tunable. FIG. 1B is a top view of the IC structure shown in FIG. 1A (Embodiment 1A) according to an example embodiment of this disclosure, and FIG. 1C is a schematic representation of the IC shown in FIG. 1A (Embodiment 1A).

More specifically, and with reference to FIGS. 1A-1C, the disclosed structure 1001A includes the following.

A first DTC structure, CapaA1, includes trench 110A with a liner 120 formed in a substrate 102, the trench 110A extending into intermetal dielectric (IMD) regions 106A and 106B formed on the substrate 102. The capacitance function of CapA1 is provided by alternating layers of electrode material E1A, E2A, E3A and E4A and high-k (HK) dielectric material HK1A, HK2A, HK3A and HK4A, which are wrapped around a filler dielectric 126 core material of the trench 110A. Operationally, to store an electrical charge within the trench 110A HK dielectric layers HK1A-HK4A, a voltage is applied to one or more of the electrodes E1A-E4A via electrical contacts, e.g.,. contact holes, 140A1, 140A2, 140A3 and 140A4, respectively.

During the fabrication process, trench 110A is etched to a total depth of TDA, where trench depth TDA is composed of an initial trench depth TDA1 within the substrate 102 and an added trench depth of TDA2 within IMD layers or regions 106A and 106B.

A second DTC structure, CapaB1, includes trench 110B with a liner 120 formed in the substrate 102, the trench 110B extending into intermetal dielectric (IMD) regions 106A and 106B formed on the substrate 102. The capacitance function of CapB1 is provided by alternating layers of electrode material E1B, E2B, E3B and E4B and high-k (HK) dielectric material HK1B, HK2B, HK3B and HK4B, which are wrapped around a filler dielectric 126 core material of the trench 110B. Operationally, to store an electrical charge within the trench 110B HK dielectric layers HK1B-HK4B, a voltage is applied to one or more of the electrodes E1B-E4B via electrical contacts, e.g.,. contact holes, 140B1, 140B2, 140B3 and 140B4, respectively.

During the fabrication process, trench 110B is etched to a total depth of TDB, where trench depth TDB is composed of an initial trench depth TDB1 within the substrate 102 and an added trench depth of TDB2 within IMD layers or regions 106A and 106B.

Distinct from CapA1, CapB1 includes a BEOL transistor 130B, e.g. (Indium-gallium-zinc-oxide (IGZO) thin film transistor (TFT)) formed on electrode E1B, and not contacting or isolated from any neighboring electrodes, the BEOL transistor including a gate region 131B, a gate dielectric region 132B and an active semiconductor region 133B made of IGZO, or other suitable semiconductor material. In operation, the BEOL transistor is selectively turned ON or OFF to tune or vary the capacitance of CapB1. Specifically, the BEOL transistor 130B functions to effectively turn ON and OFF the electrical conductivity path from a voltage source applied to the DTC device contacts 140B1 to electrode/electrode layer E1B within trench 110B, where switched electrode E1B is operatively associated with dielectric layer HK1B/HK2B used for storing a portion of the electrical charge capacitance of the device. In other words, by switching ON and OFF BEOL transistor 133B, the capacitance of the underlying DTC structure CapB1 can be tuned or adjusted, where switching ON the BEOL transistor 130B provides a relatively higher capacitance and switching OFF the BEOL transistor 130B provides a relatively lower capacitance of the device.

A third DTC structure, CapaB1, includes trench 110C with a liner 120 formed in the substrate 102, the trench 110C extending into only intermetal dielectric (IMD) region 106A (not IMD 106B as with CapA1 and CapB1) formed on the substrate 102. The capacitance function of CapC1 is provided by alternating layers of electrode material E1C, E2C, E3C and E4C and high-k (HK) dielectric material HK1C, HK2C, HK3C and HK4C, which are wrapped around a filler dielectric 126 core material of the trench 110C. Operationally, to store an electrical charge within the trench 110C HK dielectric layers HK1C-HK4C, a voltage is applied to one or more of the electrodes E1C-E4C via electrical contacts, e.g.,. contact holes, 140C1, 140C2, 140C3 and 140C4, respectively.

During the fabrication process, trench 110A is etched to a total depth of TDC, where trench depth TDC is composed of an initial trench depth TDC1 within the substrate 102 and an added trench depth of TDC2 within IMD layers or region 106A.

Distinct from CapA1, and similar to CapB1, CapC1 includes a BEOL transistor 130C, e.g. (Indium-gallium-zinc-oxide (IGZO) thin film transistor (TFT)) formed on electrode E1C, the BEOL transistor including a gate region 131C, a gate dielectric region 132C and an active semiconductor region 133C made of IGZO, or other suitable semiconductor material. In operation, the BEOL transistor is selectively turned ON or OFF to tune or vary the capacitance of CapC1. Specifically, the BEOL transistor 130C functions to effectively turn ON and OFF the electrical conductivity path from a voltage source applied to the DTC device contacts 140C1 to electrode/electrode layer E1C within trench 110C, where switched electrode E1B is operatively associated with dielectric layer HK1C/HK2C used for storing a portion of the electrical charge capacitance of the device. In other words, by switching ON and OFF BEOL transistor 130C, the capacitance of the underlying DTC structure CapC1 can be tuned or adjusted, where switching ON the BEOL transistor 130C provides a relatively higher capacitance and switching OFF the BEOL transistor 130C provides a relatively lower capacitance of the device.

A patterned metallization or metal layer M2 (2-N) 152 is patterned and formed to electrical interface and connect the DTC CapA1 and CapB1 structure to an external circuit and provide the necessary interconnections of the electrodes for the desired operation of the DTCs. In addition, metallization or metal layer M1 151, Vias 160 and M2 (2-N) 152 are formed to electrical interface and connect the DTC CapC1 structure to an external circuit and provide the necessary interconnections of the electrodes for the desired operation of the DTCs, such as selectively connecting DTC structures. To accommodate variations in capacitance, an extensive design of the metal layers 151 can be implemented, where, for example, the depth of a DTC trench can be individually varied within the intermetal dielectrics of different Metal (2 to N) layers. Also, as will be described with reference to FIG. 1C below, the connections for Hi-Volt 4 and Lo-Volt 2 on the upper metal layers can be on the same layer or on different metal layers.

During the DTC trench fabrication process, etch stop layers 104A, 104B, 104C, 104D and 104E are used to provide the necessary etch process stopping functions to fabricate the various DTC structural layers and features described and shown in FIG. 1A, including, but not limited to, IMD regions 106A, 106B, 106C, 106D and 106E. A passivation layer 180 is formed on the entire DTC structure, which protects the DTC structure from the surrounding environment.

With reference to FIG. 1C, as well as FIGS. 1A and 1B for understanding, an equivalent circuit of a 4 electrode/3 capacitor structure is shown, the equivalent circuit including capacitors C1, C2 and C3, as well as Hi-Voltage potential connection/source 4 and Low-Voltage potential connection/source 2. The shown equivalent capacitance circuit is representative of a single DTC structure, i.e., CapA1, CapB1and/or CapC1 as shown in FIGS. 1A and 1B.

The 4 electrode/ 3capacitor structure corresponds to Embodiment 1A 1001A as follows:

C1, C2 and C3 each represent electrode-dielectric-electrode alternating layers, where E1A-HK1A-E2A is represented as C1; E2A-HK2A-E3A is represented as C2; and E3A-HK3A-E4A is represented as C4. Tunable device 130B of FIG. 1C represents, for example, CapB1 BEOL transistor 130B. The optional tunable device shown in the schematic of FIG. 1C is shown simply to indicate that any one or more of the DTC devices or structures can be formed to include a BEOL transistor on an electrode to provide the ability to switch a capacitive leg in the trench of the DTC structure ON or OFF, thereby providing a tuning or adjustable capacitance function to the DTC. Also, as shown in FIG. 1A, each of the electrodes and HK dielectric charge retention regions extends a different length around a DTC trench, where outer electrodes/HK dielectric layers are longer than the inner electrodes/HK dielectric layers. As a result the outer electrodes/HK dielectric layers have a relatively higher capacitance than the inner electrodes/HK dielectric layers.

In operation, the BEOL transistor can be independently controlled through applying a gate voltage. Its working principle involves adjusting the gate voltage to control whether current flows through the BEOL transistor. Different gate voltage levels can be applied through various metal pattern designs, or the thickness of the BEOL transistor can be adjusted to change the voltage it can withstand. This allows for the fine-tuning of a desired capacitance to suit the needs of the voltage requirements of a product or device.

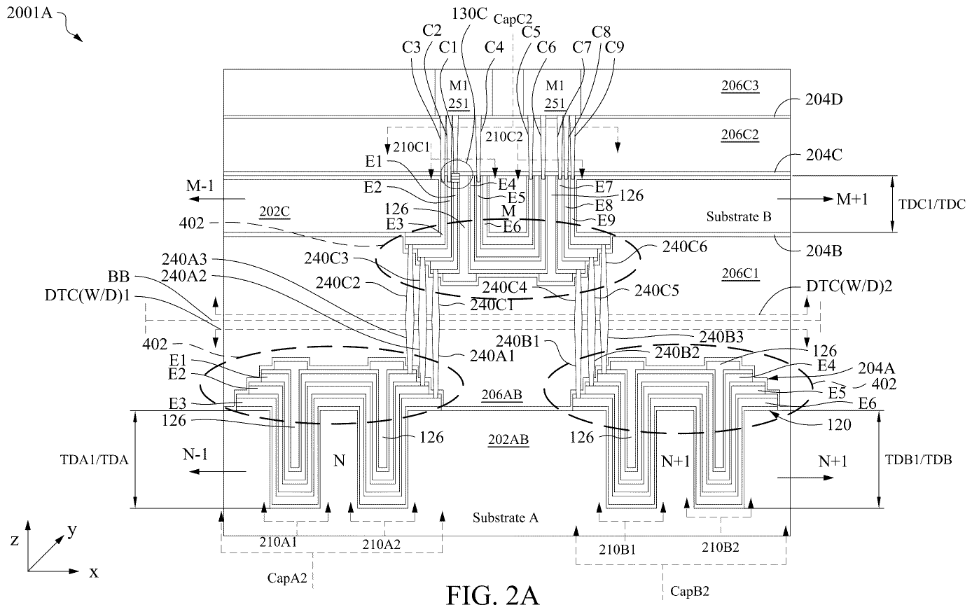

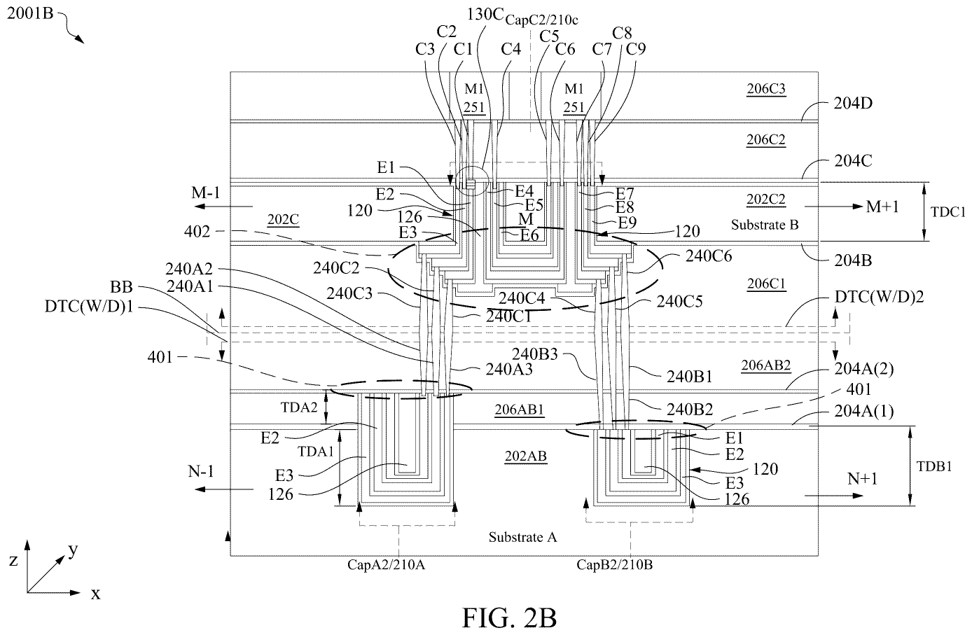

Other features of the disclosed DTC structure shown in FIGS. 1A and 1B include a planar type structure, including a planar shaped electrode contact interface structure or interconnect structure 401, as compared to a stair shaped MIM electrode contact interface structure 402 or nonplanar profile as shown in FIG. 2B. Furthermore, the disclosed DTC structure of Embodiment 1A 1001A provides a structure that accommodates DTC devices, e.g., CapA1, CapB1, and CapC1, which have different trench depths, or more generally different type of DTC device or structures themselves.

According to some example embodiments, the substrates used herein may comprise an advanced chip or silicon base wafer.

According to some example embodiments, the DTC electrodes may be comprised of TiN, Ru, carbon, polysilicon . . .etc, and the DTC high-k capacitor dielectric may be comprised of aluminum oxide (Al2O3), zirconium dioxide (ZrO2), hafnium dioxide (HfO2), etc.

According to some example embodiments, the DTC stacking structures can be any number of layers of electrode/high-k capacitor dielectric films, any number of layers of intermetal dielectric films and metals, and the DTC trenches are not limited to a particular shape or profile for use within a silicon substate and/or intermetal dielectric film.

With reference to FIG. 1D, shown is a cross sectional view of an integrated circuit (IC) structure (Embodiment 1B) including a planar type tunable stacking structure for a deep trench capacitor (DTC) structure according to an example embodiment of the present disclosure, this embodiment including discrete DTC structures CapA1, CapB1 and CapC1 where CapA1 and CapB1 DTC structures each have trenches that extend from an intermetal dielectric region into the substrate, CapC1 DTC structure has a relatively shallower trench only within the intermetal dielectric region, each of the DTC structures have planar electrode contact interfaces 401, and DTC structures CapB1 and CapC2 are tunable.

According to this embodiment, and distinct from Embodiment 1A 1001A, the DTC structure includes a plurality of DTC structures, where all of the DTC trenches do not extend into the substrate 102. DTC CapC1 trench 110C is etched in the IMD region 106A, only, and has a trench depth of TDC/TDC2.

With reference to FIG. 1E, shown is a cross sectional view of an integrated circuit (IC) structure (Embodiment 1C) including a planar type tunable stacking structure for a deep trench capacitor (DTC) structure according to an example embodiment of the present disclosure. Distinct from Embodiment 1A 1001A and Embodiment 1B, this embodiment includes discrete DTC structures CapA1, CapB1 and CapC1 where CapA1 and CapB1 DTC structures each have trenches, 110A and 110B respectively, that extend from an intermetal dielectric region 106A and 106B into the substrate 102, and CapC1 DTC structure includes a relatively shallower trench 110C only within the substrate 102. As previously described to Embodiments 1A 1001A and Embodiment 1B 1001B, each of the DTC structures have planar electrode contact interfaces 401, and DTC structures CapB1 and CapC2 are tunable.

With reference to FIG. 2A, shown is a cross sectional view of an integrated circuit (IC) structure (Embodiment 2A) including a 2.5D-like type tunable stacking structure for a deep trench capacitor (DTC) structure, including a single sided metal patterned circuit or layer/line 251 for electrical connections to an external device and/or configuring and control of the underlying DTC structures CapA2, CapB2 and CapC2 according to an example embodiment of the present disclosure. In contrast to Embodiments 1A 1001A, 1B 1001B and 1C 1001C, Embodiment 2A 2001A includes a 2.5D type stacked structure of DTC wafers, or dies, DTC(W/D)1 and DTC(W/D)2, where each DTC wafer has a stair shaped metal-insulator-metal (MIM) electrode contact interface structure 402 extending into an intermetal dielectric region, where CapA2 and CapB2 DTC structures each have dual trenches 210A1 and 210A2, and 210B1 and 210B2, respectively, only within the first substrate 202AB of wafer DTC(W/D)1, and CapC2 DTC structure has a dual trench 210C12 and 210C2 only within the second substrate 202C of wafer DTC(W/D)2.

DTC structure CapC2 is tunable by transistor 130C which is operatively/selectively connected to CapC2 electrode E1 to increase the capacitance of the structure, and the wafers DTC(W/D)1 and DTC(W/D)2 are bonded at or near bonding boundary BB by bonding contact hole pairs 240A1,240C1; 240A2,240C2; 240A3,240C3; 240B1,240C4; 240B2,240C5; and 240B3,240C6. As shown in FIG. 2A, this embodiment can include N DTC structures, where N+1 and N−1 DTC structures or dies are formed adjacent to CapA2 and CapB2 on wafer DTC(W/D)1, where N=1, 2, . . . N. Furthermore, this embodiment can include M DTC structures, where M+1 and M−1 DTC structures or dies are formed adjacent to CapC2 on wafer DTC(W/D)2, where M=1, 2, . . . M.

More specifically, the disclosed structure 2001A includes the following.

A first DTC structure, CapA2, includes dual trenches 210A1 and 210A2 with a liner 120 formed in a substrate 202AB. The capacitance function of CapA21 is provided by alternating layers of electrode material E1, E2, and E3 and a high-k (HK) dielectric material (not identified by reference character in FIG. 2A for clarity), which are wrapped around a filler dielectric 126 core material of the trenches 210A1 and 210A2. Operationally, to store an electrical charge within the trenches 210A1 and 210A2 HK dielectric layers, a voltage is applied to one or more of the electrodes E1-E3 via electrical contacts, e.g.,. contact holes, 240A1, 240A2, and 240A3, respectively.

During the fabrication process, trenches 210A1 and 210A2 are etched to a total depth of TDA1/TDA, where trench depth TDA1/TDA is within the substrate 202AB. A stair shaped MIM electrode contact interface structure 402 formed on the substrate 202AB within IMD region 206AB provides the necessary electrode connections to contacts 240A1, 240A2 and 240A3.

A second DTC structure, CapB2, formed similarly to the formation of CapA2, includes dual trenches 210B1 and 210B2 with a liner 120 formed in the substrate 202AB. The capacitance function of CapB2 is provided by alternating layers of electrode material E1, E2, and E3 and high-k (HK) dielectric material (not identified by reference character in FIG. 2A for clarity), which are wrapped around a filler dielectric 126 core material of the trenches 210B1 and 210B2. Operationally, to store an electrical charge within the trench 210B1 and 210A2, HK dielectric layers, a voltage is applied to one or more of the electrodes E1-E3 via electrical contacts, e.g.,. contact holes, 240B1, 240B2, and 240B3, respectively.

During the fabrication process, trenches 210B1 and 210B2 are etched to a total depth of TDB1/TDB, where trench depth TDB1/TDB is within the substrate 202AB. A stair shaped MIM electrode contact interface structure 402 is formed on the substrate 202AB within IMD region 206AB and provides the necessary electrode connections to contacts 240B1, 240B2 and 240B3.

A third DTC structure, CapC2, formed similarly to the formation of CapA2 and CapB2 on another substrate 202C, i.e., wafer or die DTC(W/D)2, includes dual trenches 210C1 and 210C2 with a liner 120 formed in the substrate 202C. The capacitance function of CapC2 is provided by alternating layers of electrode material E1-E9 and high-k (HK) dielectric material layers (not identified by reference character in FIG. 2A for clarity), which are wrapped around a filler dielectric 126 core material of the trenches 210C1 and 210C2. Operationally, to store an electrical charge within the trench 210C1 and 210C2 HK dielectric layers, a voltage is applied to one or more of the electrodes E1-E9 via electrical contacts, e.g.,. contact holes, C1-C9, respectively.

During the fabrication process, trenches 210C1 and 210C2 are etched to a total depth of TDC1/TDC, where trench depth TDC1/TDC is within the substrate 202C. A stair shaped MIM electrode contact interface structure 402 formed on the substrate 202C within IMD region 206C1 provides the necessary electrode connections to contacts 240C1-240C6 of wafer/die DTC(W/D)1.

Distinct from CapA2 and CapB2, CapC2 includes a BEOL transistor 130C, e.g. (Indium-gallium-zinc-oxide (IGZO) thin film transistor (TFT)) formed on electrode E1C, and not contacting or isolated from any neighboring electrodes, the BEOL transistor including a gate region 131C, a gate dielectric region 132C and an active semiconductor region 133C made of IGZO, or other suitable semiconductor material. In operation, the BEOL transistor is selectively turned ON or OFF to tune or vary the capacitance of CapC2. Specifically, the BEOL transistor 130C functions to effectively turn ON and OFF the electrical conductivity path from a voltage source applied to the DTC device contact C1 to electrode/electrode layer E1 within trench 210C1, where switched electrode E1 is operatively associated with dielectric layers used for storing a portion of the electrical charge capacitance of the device. In other words, by switching ON and OFF BEOL transistor 130C, the capacitance of the underlying DTC structure CapC2 can be tuned or adjusted, where switching ON the BEOL transistor 130C provides a relatively higher capacitance and switching OFF the BEOL transistor 130C provides a relatively lower capacitance of the device.

A patterned metallization or metal layer M1 251 is patterned and formed to provide a one sided metallization connection electrical interface and connect the DTC CapC2 structure to an external circuit and provide the necessary interconnections of the electrodes for the desired operation of the DTCs, such as selectively connecting DTC structures, such as selectively connecting DTC structures.

During the DTC trench fabrication process, etch stop layers 204A, 204B, 204C, and 204D are used to provide the necessary etch process stopping functions to fabricate the various DTC structural layers and features described and shown in FIG. 2A, including, but not limited to, IMD regions 206AB, 206C1, 206C2, 206C3. A passivation layer (not shown) is formed on the entire DTC structure, which protects the DTC structure from the surrounding environment.

With reference to FIG. 2B, shown is a cross sectional view of an integrated circuit (IC) structure (Embodiment 2B) including a 2.5D-like type tunable stacking structure for a deep trench capacitor (DTC) structure according to an example embodiment of the present disclosure, this embodiment including discrete DTC structures CapA2, CapB2 and CapC2 where CapA2 DTC structure has a trench that extend from a first intermetal dielectric region into a first substrate including a planar electrode contact interface 401, CapB2 DTC structure extends only into the first substrate including a planar electrode contact interface 401, and CapC2 has a trench only within a second substrate including a stair shaped MIM electrode contact interface 402 extending into a second intermetal dielectric region, and DTC structure CapC2 is tunable to operatively/selectively connected to CapA2's outer capacitor electrode to increase the capacitance of the structure.

DTC structure CapC2 is tunable by transistor 130C which is operatively/selectively connected to CapC2 electrode E1 to increase the capacitance of the structure., and the wafers DTC(W/D)1 and DTC(W/D)2 are bonded at or near bonding boundary BB by bonding contact hole pairs 240A1,240C1; 240A2,240C2; 240A3,240C3; 240B1,240C4; 240B2,240C5; and 240B3,240C6. As shown in FIG. 2B, this embodiment can include N DTC structures, where N+1 and N−1 DTC structures or dies are formed adjacent to CapA2 and CapB2 on wafer DTC(W/D)1, where N=1, 2, . . .N. Furthermore, this embodiment can include M DTC structures, where M+1 and M−1 DTC structures or dies are formed adjacent to CapC2 on wafer DTC(W/D)2, where M=1, 2, . . .M.

More specifically, the disclosed structure 2001B includes the following.

A first DTC structure, CapA2, includes trenches 210A with a liner 120 formed in a substrate 202AB. The capacitance function of CapA2 is provided by alternating layers of electrode material E1, E2, and E3 and a high-k (HK) dielectric material (not identified by reference character in FIG. 2A for clarity), which are wrapped around a filler dielectric 126 core material of trench 210A. Operationally, to store an electrical charge within trenches 210A HK dielectric layers, a voltage is applied to one or more of the electrodes E1-E3 via electrical contacts, e.g.,. contact holes, 240A1, 240A2, and 240A3, respectively.

During the fabrication process, trench 210A and 210A2 is etched to a total depth of TDA, where trench depth TDA1 is within the substrate 202AB and an additional trench depth TDA2 is etched in IMD region 206AB1. A planar shaped electrode contact interface structure 401 is formed on the substrate 202AB within IMD region 206AB and provides the necessary electrode connections to contacts 240A1, 240A2 and 240A3.

A second DTC structure, CapB2 includes trenches 210B with a liner 120 formed in the substrate 202AB. The capacitance function of CapB2 is provided by alternating layers of electrode material E1, E2, and E3 and a high-k (HK) dielectric material (not identified by reference character in FIG. 2A for clarity), which are wrapped around a filler dielectric 126 core material of trenches 210B. Operationally, to store an electrical charge within the trench 210B HK dielectric layers, a voltage is applied to one or more of the electrodes E1-E3 via electrical contacts, e.g.,. contact holes, 240B1, 240B2, and 240B3, respectively.

During the fabrication process, trench 210B is etched to a total depth of TDB1, where trench depth TDB1 is entirely or completely within the substrate 202AB. A planar shaped electrode contact interface structure 401 is formed on the substrate 202AB and provides the necessary electrode connections to contacts 240B1, 240B2 and 240B3.

A third DTC structure, CapC2, is formed similarly to the formation of CapC2 of Embodiment 2001A as described above with reference to FIG. 2A and is not repeated here. Distinct from CapA2 and CapB2, CapC2 includes a BEOL transistor 130C, e.g. (Indium-gallium-zinc-oxide (IGZO) thin film transistor (TFT)) formed on electrode E1C, and not contacting or isolated from any neighboring electrodes, the BEOL transistor including a gate region 131C, a gate dielectric region 132C and an active semiconductor region 133C made of IGZO, or other suitable semiconductor material as previously described with reference to FIG. 2A CapC2.

A patterned metallization or metal layer M1 251 is patterned and formed to provide a one sided metallization connection electrical interface and connect the DTC CapC2 structure to an external circuit and provide the necessary interconnections of the electrodes for the desired operation of the DTCs, such as selectively connecting DTC structures.

During the DTC trench fabrication process, etch stop layers 204A(1), 204A(2), 204B, 204C, and 204D are used to provide the necessary etch process stopping functions to fabricate the various DTC structural layers and features described and shown in FIG. 2A, including, but not limited to, IMD regions 206AB1, 206AB2, 206C1, 206C2, 206C3. A passivation layer (not shown) is formed on the entire DTC structure, which protects the DTC structure from the surrounding environment.

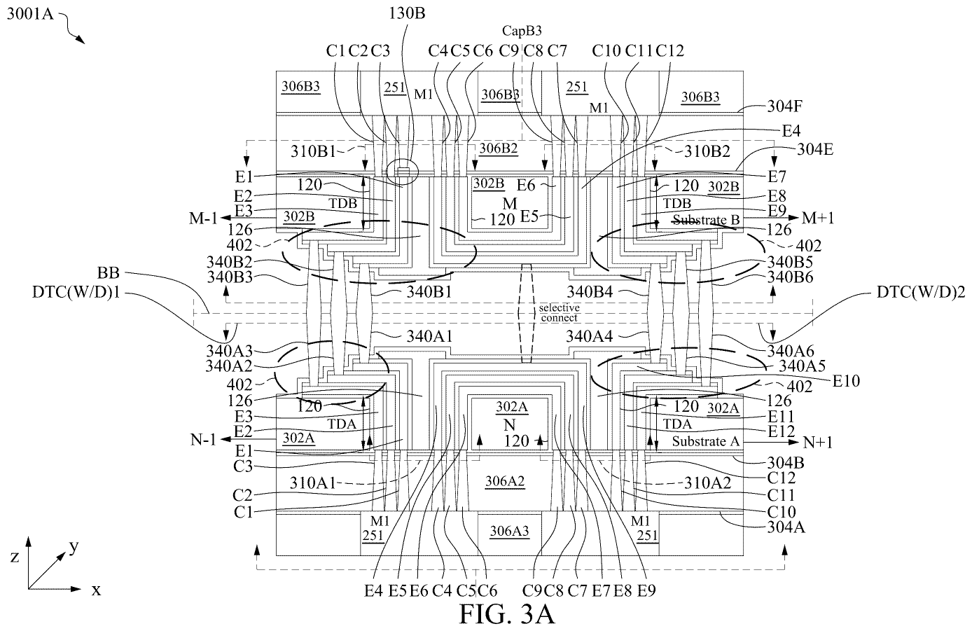

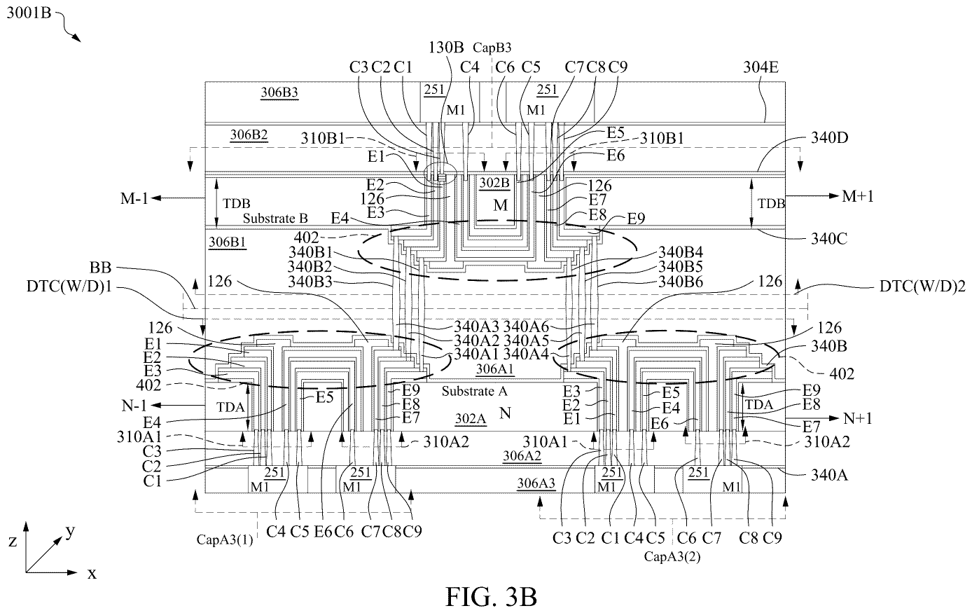

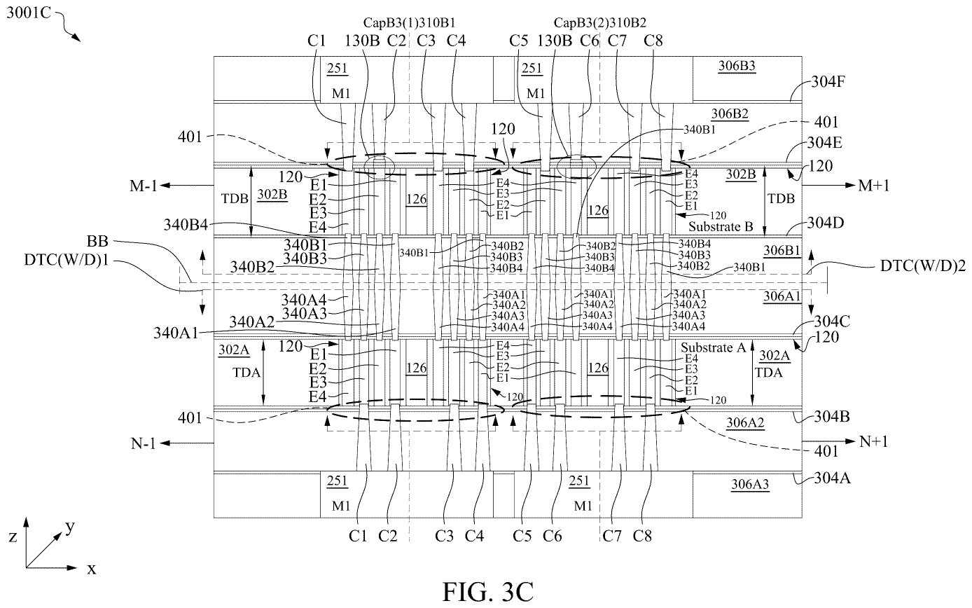

With reference to FIG. 3A, shown is a cross sectional view of an integrated circuit (IC) structure (Embodiment 3A) 3001A including a 3D-like type tunable stacking structure for a deep trench capacitor (DTC) structure according to an example embodiment of the present disclosure, this embodiment including discrete DTC structures CapA3 and CapB3, each including a stair shaped metal-insulator-metal (MIM) electrode contact interface 402 extending into an intermetal dielectric region, where CapA3 DTC structure has dual trenches that extend only within a first substrate, CapB3 DTC structure has dual trenches that extend only within a second substrate, and DTC structure CapB3 is tunable to operatively/selectively connected to one of CapA2's capacitor electrodes to increase the capacitance of the structure.

DTC structure CapB3 is tunable by transistor 130B which is operatively/selectively connected to CapB3 electrode E1 to increase the capacitance of the structure, and the wafers DTC(W/D)1 and DTC(W/D)2 are bonded at or near bonding boundary BB by bonding contact hole pairs 340A1,340B1; 340A2,340B2; 340A3,340B3; 340A4,340B4; 340A5,340B5; and 340A6,340B6. As shown in FIG. 3A, this embodiment can include N DTC structures, where N+1 and N−1 DTC structures or dies are formed adjacent to CapA3 on wafer DTC(W/D)1, where N=1, 2, . . .N. Furthermore, this embodiment can include M DTC structures, where M+1 and M−1 DTC structures or dies are formed adjacent to CapB3 on wafer DTC(W/D)2, where M=1, 2, . . . M. Also, the DTC structure includes a “Selective Connect” configuration where electrodes in a DTC can be selectively not connected or connected in the middle, depending on the desired capacitance of the structure and/or product requirements.

More specifically, the disclosed structure 3001A includes the following.

A first DTC structure, CapA3, including dual trenches 310A1 and 310A2 with a liner 120 formed in a substrate 302A. The capacitance function of CapA3 is provided by alternating layers of electrode material E1, E2, and E3 and a high-k (HK) dielectric material (not identified by reference character in FIG. 3A for clarity), which are wrapped around a filler dielectric 126 core material of the trenches 310A1 and 310A2. Operationally, to store an electrical charge within the trenches 310A1 and 310A2 HK dielectric layers, a voltage is applied to one or more of the electrodes E1-E3 via electrical contacts, e.g.,. contact holes, 340A1, 340A2, and 340A3, and/or E9-E12 via electrical contacts, e.g.,. contact holes, 340A4, 340A5, and 340A6, respectively, or electrodes E1-E12 and electrical contacts C1-C12, respectively.

During the fabrication process, trenches 310A1 and 310A2 are etched to a total depth of TDA, where trench depth TDA is completely within the substrate 302A. A stair shaped MIM electrode contact interface structure 402 formed on the substrate 302A within IMD region 306A1 provides the necessary electrode connections to contacts 340A1, 340A2 and 340A3.

A second DTC structure, CapB3, formed similarly to the formation of CapA3, includes dual trenches 310B1 and 310B2 with a liner 120 formed in the substrate 302B. The capacitance function of CapB3 is provided by alternating layers of electrode material E1, E2, and E3 and high-k (HK) dielectric material (not identified by reference character in FIG. 3A for clarity), which are wrapped around a filler dielectric 126 core material of the trenches 310B1 and 310B2. Operationally, to store an electrical charge within the trenches 310B1 and 310B2 HK dielectric layers, a voltage is applied to one or more of the electrodes E1-E12 via electrical contacts, e.g.,. contact holes, C1-C12, respectively.

During the fabrication process, trenches 310B1 and 310B2 are etched to a total depth of TDB, where trench depth TDB is completely within the substrate 302B. A stair shaped MIM electrode contact interface structure 402 is formed on the substrate 302B within IMD region 306B1 and provides the necessary electrode connections to contacts 340B1, 340B2, 340B3, 340B4, 340B5 and 340B6.

Distinct from CapA3 and CapB3 includes a BEOL transistor 130B, e.g. (Indium-gallium-zinc-oxide (IGZO) thin film transistor (TFT)) formed on electrode E1, and not contacting or isolated from any neighboring electrodes, the BEOL transistor including a gate region, a gate dielectric region and an active semiconductor region made of IGZO, or other suitable semiconductor material. In operation, the BEOL transistor is selectively turned ON or OFF to tune or vary the capacitance of CapB3. Specifically, the BEOL transistor 130B functions to effectively turn ON and OFF the electrical conductivity path from a voltage source applied to the DTC device contact C1 to electrode/electrode layer E1 within trench 310B1, where switched electrode E1 is operatively associated with dielectric layers used for storing a portion of the electrical charge capacitance of the device. In other words, by switching ON and OFF BEOL transistor 130B, the capacitance of the underlying DTC structure CapB3 can be tuned or adjusted, where switching ON the BEOL transistor 130C provides a relatively higher capacitance and switching OFF the BEOL transistor 130C provides a relatively lower capacitance of the device.

A patterned metallization or metal layer M1 251 is patterned and formed to provide a two sided metallization connection electrical interface and connect the DTC CapA3 and CapB3 structure to an external circuit and provide the necessary interconnections of the electrodes for the desired operation of the DTCs, such as selectively connecting DTC structures.

During the DTC trench fabrication process, etch stop layers 304A, 304B, 304C, 304D, 304E and 304F are used to provide the necessary etch process stopping functions to fabricate the various DTC structural layers and features described and shown in FIG. 3A, including, but not limited to, IMD regions 306A1, 306A2, 306A3, 306B1, 306B2 and 306B3. A passivation layer (not shown) is formed on the entire DTC structure, which protects the DTC structure from the surrounding environment.

With reference to FIG. 3B, shown is a cross sectional view of an integrated circuit (IC) structure (Embodiment 3B) 3001B including a 3D-like type tunable stacking structure for a deep trench capacitor (DTC) structure according to an example embodiment of the present disclosure, this embodiment including discrete DTC structures CapA3(1), CapA3(2) and CapB3, each including a stair shaped metal-insulator-metal (MIM) electrode interface 402 extending into an intermetal dielectric region, where CapA3(1) and CapA3(2) DTC structures each have trenches that extend only within a first substrate, CapB3 DTC structure has a trench that extends only within a second substrate, and CapB3 is tunable to operatively/selectively connect to one of CapB3's electrodes to increase the capacitance of the structure.

As previously described with reference to FIG. 3A, DTC structure CapB3 is tunable by transistor 130B which is operatively/selectively connected to CapB3 electrode E1 to increase the capacitance of the structure, and the wafers DTC(W/D)1 and DTC(W/D)2 are bonded at or near bonding boundary BB by bonding contact hole pairs 340A1,340B1; 340A2,340B2; 340A3,340B3; 340A4,340B4; 340A5,340B5; and 340A6,340B6. As shown in FIG. 3B, this embodiment can include N DTC structures, where N+1 and N−1 DTC structures or dies are formed adjacent to CapA3(1) and/or CapA3(2) on wafer DTC(W/D)1, where N=1, 2, . . .N. Furthermore, this embodiment can include M DTC structures, where M+1 and M−1 DTC structures or dies are formed adjacent to CapB3 on wafer DTC(W/D)2, where M=1, 2, . . . M.

For further details of Embodiment 3B 3001B, refer to FIG. 3A and the associated detailed description of FIG. 3A which describes identical DTC structures CapA3 and CapB3.

A patterned metallization or metal layer M1 251 is patterned and formed to provide a two sided metallization connection electrical interface and connect the DTC CapA3(1) and CapA3(2), and CapB3 structure to an external circuit and provide the necessary interconnections of the electrodes for the desired operation of the DTCs, such as selectively connecting DTC structures.

During the DTC trench fabrication process, etch stop layers 304A, 304B, 304C, 304D, and 304E are used to provide the necessary etch process stopping functions to fabricate the various DTC structural layers and features described and shown in FIG. 3B, including, but not limited to, IMD regions 306A1, 306A2, 306A3, 306B1, 306B2 and 306B3. A passivation layer (not shown) is formed on the entire DTC structure, which protects the DTC structure from the surrounding environment.

With reference to FIG. 3C, shown is a cross sectional view of an integrated circuit (IC) structure (Embodiment 3C) 3001C including a 3D-like type tunable stacking structure for a deep trench capacitor (DTC) structure according to an example embodiment of the present disclosure, this embodiment including discrete DTC structures CapA3(1), CapA3(2), CapB3(1) and CapB3(2), each including planar electrode contact interfaces 401, where CapA3(1) and CapA3(2) DTC structures each have trenches that extend only within a first substrate 302A, CapB3(1) and CapC3(2) DTC structure have trenches that extend only within a second substrate 302B, CapB3(1) is tunable to operatively/selectively connect to one of CapA3(1)'s electrodes to increase the capacitance of the structure, and CapB3(2) is tunable to operatively/selectively connect to one of CapA3(2)'s electrodes to increase the capacitance of the structure.

DTC structure CapB3(2) is tunable by transistor 130B which is operatively/selectively connected to CapB3 electrode E1 to increase the capacitance of the structure, and the wafers DTC(W/D)1 and DTC(W/D)2 are bonded at or near bonding boundary BB by bonding contact hole pairs 340A1,340B1; 340A2,340B2; 340A3,340B3; and 340A4,340B4 for each of DTC structures CapA3(1), CapA3(2), CapB3(1) and CapB3(2). As shown in FIG. 3C, this embodiment can include N DTC structures, where N+1 and N−1 DTC structures or dies are formed adjacent to CapA3(1) and/or CapA3(2) on wafer DTC(W/D)1, where N=1, 2, . . . N. Furthermore, this embodiment can include M DTC structures, where M+1 and M−1 DTC structures or dies are formed adjacent to CapB3(1) and/or CapB3(2) on wafer DTC(W/D)2, where M=1, 2, . . . M.

More specifically, the disclosed structure 3001A includes the following.

A first DTC structure, CapA3(1), includes trench 310A1 with a liner 120 formed in a substrate 302A. The capacitance function of CapA3(1) is provided by alternating layers of electrode material E1, E2, E3 and E4 and a high-k (HK) dielectric material (not identified by reference character in FIG. 3A for clarity), which are wrapped around a filler dielectric 126 core material of the trench 310A1. Operationally, to store an electrical charge within the trench 310A1HK dielectric layers, a voltage is applied to one or more of the electrodes E1-E4 via electrical contacts, e.g.,. contact holes, 340A1, 340A2, 340A3 and 340A4, respectively, and/or via electrical contacts C1-C4.

During the fabrication process, trench 310A1 is etched to a total depth of TDA, where trench depth TDA is completely within the substrate 302A. A planar shaped electrode contact interface structure 401 is formed on the substrate 302A to provide the necessary electrode connections to contacts 340A1, 340A2, 340A3 and 340A4, contacts C1-C4.

A second DTC structure, CapA3(2), includes trench 310A2 with a liner 120 formed in a substrate 302A. The capacitance function of CapA3(2) is provided by alternating layers of electrode material E1, E2, E3 and E4 and a high-k (HK) dielectric material (not identified by reference character in FIG. 3C for clarity), which are wrapped around a filler dielectric 126 core material of the trench 310A2. Operationally, to store an electrical charge within the trench 310A2 HK dielectric layers, a voltage is applied to one or more of the electrodes E1-E4 via electrical contacts, e.g.,. contact holes, 340A1, 340A2, 340A3 and 340A4, respectively, and/or via electrical contacts C1-C4.

During the fabrication process, trench 310A2 is etched to a total depth of TDA, where trench depth TDA is completely within the substrate 302A. A planar shaped electrode contact interface structure 401 is formed on the substrate 302A to provide the necessary electrode connections to contacts 340A1, 340A2, 340A3 and 340A4, contacts C1-C4.

A third DTC structure, CapB3(1), includes trench 310B1 with a liner 120 formed in a substrate 302B. The capacitance function of CapB3(1) is provided by alternating layers of electrode material E1, E2, E3 and E4 and a high-k (HK) dielectric material (not identified by reference character in FIG. 3C for clarity), which are wrapped around a filler dielectric 126 core material of the trench 310B1. Operationally, to store an electrical charge within the trench 310B1 HK dielectric layers, a voltage is applied to one or more of the electrodes E1-E4 via electrical contacts, e.g.,. contact holes, 340B1, 340B2, 340B3 and 340B4, respectively, and/or via electrical contacts C1-C4.

During the fabrication process, trench 310B1 is etched to a total depth of TDA, where trench depth TDA is completely within the substrate 302B. A planar shaped electrode contact interface structure 401 is formed on the substrate 302B to provide the necessary electrode connections to contacts 340B1, 340B2, 340B3 and 340B4, contacts C1-C4.

A fourth DTC structure, CapB3(2), includes trench 310B2 with a liner 120 formed in a substrate 302B. The capacitance function of CapB3(2) is provided by alternating layers of electrode material E1, E2, E3 and E4 and a high-k (HK) dielectric material (not identified by reference character in FIG. 3C for clarity), which are wrapped around a filler dielectric 126 core material of the trench 310B2. Operationally, to store an electrical charge within the trench 310B2 HK dielectric layers, a voltage is applied to one or more of the electrodes E1-E4 via electrical contacts, e.g.,. contact holes, 340B1, 340B2, 340B3 and 340B4, respectively, and/or via electrical contacts C1-C4.

During the fabrication process, trench 310B2 is etched to a total depth of TDA, where trench depth TDA is completely within the substrate 302B. A planar shaped electrode contact interface structure 401 is formed on the substrate 302B to provide the necessary electrode connections to contacts 340B1, 340B2, 340B3 and 340B4, contacts C1-C4.

Patterned metallization or metal layer(s) M1 251 is patterned and formed to provide a two sided metallization connection electrical interface and connect the DTC CapA3(1) and CapA3(2), and CapB3(1) and CapB3(2) structure to an external circuit and provide the necessary interconnections of the electrodes for the desired operation of the DTCs, such as selectively connecting DTC structures.

During the DTC trench fabrication process, etch stop layers 304A, 304B, 304C, 304D, 304E and 304F are used to provide the necessary etch process stopping functions to fabricate the various DTC structural layers and features described and shown in FIG. 3B, including, but not limited to, IMD regions 306A1, 306A2, 306A3, 306B1, 306B2 and 306B3. A passivation layer (not shown) is formed on the entire DTC structure, which protects the DTC structure from the surrounding environment.

According to some example embodiments, and with reference to Embodiments 1A, 1B, 1C, 2A, 2B, 3A, 3B and 3C, the thickness of the electrodes, high-k capacitor dielectric, filled dielectric material, etch stop layers and trench liner can vary and is about 1A to about 10 μm.

According to some example embodiments, and with reference to Embodiments 1A, 1B, 1C, 2A, 2B, 3A, 3B and 3C, the thickness of intermetal dielectric can vary and is about 1A to about 1 mm; the thickness of the BEOL transistor can vary and is about 1A to about 1 μm; the trench depth (i.e. TDA, TDB and TDC) ranges from about 1 nm to about 500 μm; the contact hole size ranges from about 1 nm to about 1 cm. Furthermore, by aligning the contact holes and using a thermal compression bonding process, along with adjustable hole sizes, the precision of the alignment can be improved.

According to an example embodiment, the Embodiments 1A, 1B, 1C, 2A, 2B, 3A, 3B and 3C are formed on one or more wafers made of a semiconducting material, where the DTC embodiment structures are built or formed thereon by related semiconductor fabrication techniques, including but not limited to photolithographic techniques such as applying a pattern/structure in a given layer by applying a photoresist layer, patterning the photoresist layer, developing the photoresist layer, and then etching, followed by planarizing and cleaning. While the specific semiconductor fabrication processes required to form the disclosed embodiments shown and described are not the focus of this disclosure, for completeness a general description of the semiconductor fabrication processes follows.

The semiconductor substrate materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center region of the substrate. The speed of the rotating platen is then increased to spread the resist evenly from the center region of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF4), hexafluoroethane (C2F6), octafluoropropane (C3F8), fluoroform (CHF3), difluoromethane (CH2F2), fluoromethane (CH3F), trifluoromethane (CHF3), carbon fluorides, nitrogen (N2), hydrogen (H2), oxygen (O2), argon (Ar), xenon (Xe), xenon difluoride (XeF2), helium (He), carbon monoxide (CO), carbon dioxide (CO2), fluorine (F2), chlorine (Cl2), oxygen (O2), hydrogen bromide (HBr), hydrofluoric acid (HF), nitrogen trifluoride (NF3), sulfur hexafluoride (SF6), boron trichloride (BCl3), ammonia (NH3), bromine (Br2), nitrogen trifluoride (NF3), or the like, or combinations thereof in various ratios. For example, silicon dioxide can be wet etched using hydrofluoric acid and ammonium fluoride. Alternatively, silicon dioxide can be dry etched using various mixtures of CHF3, O2, CF4, and/or H2.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, diluted HF, and other related solutions.

Dielectric structures or layers of the devices disclosed can be made from any suitable combination of dielectric materials. Examples of dielectric materials may include silicon dioxide (SiO2), silicon nitride (Si3N4), silicon carbide (SiC), hafnium dioxide (HfO2), zirconium dioxide (ZrO2), aluminum oxide (Al2O3), silicon oxynitride (SiOxNy), hafnium oxynitride (HfOxNy) or zirconium oxynitride (ZrOxNy), or hafnium silicates (ZrSixOy) or zirconium silicates (ZrSixOy) or silicon carboxynitride (SiCxOyNz), or hexagonal boron nitride (hBN). Other dielectric materials may include tantalum oxide (Ta2O5), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material, discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

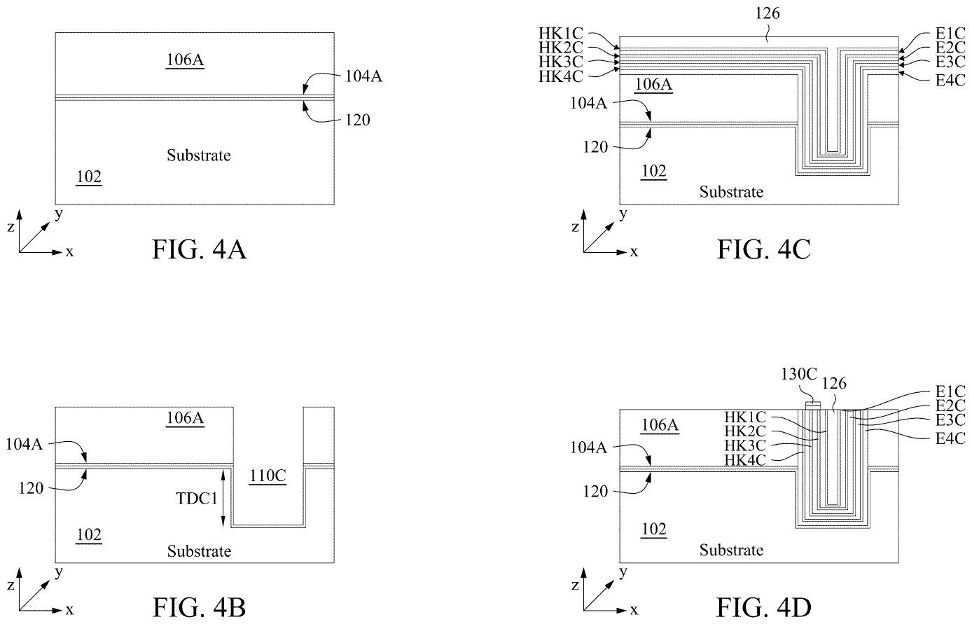

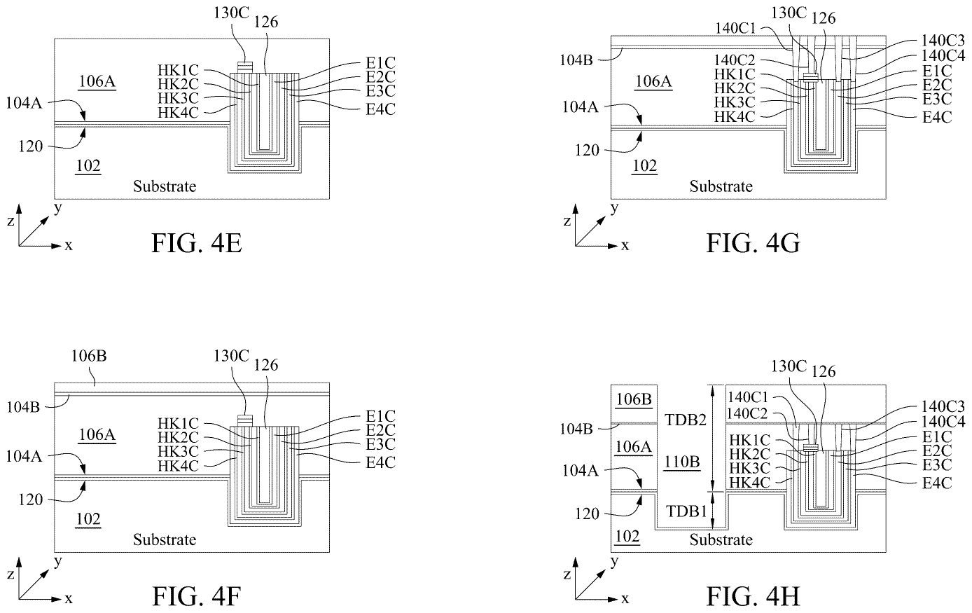

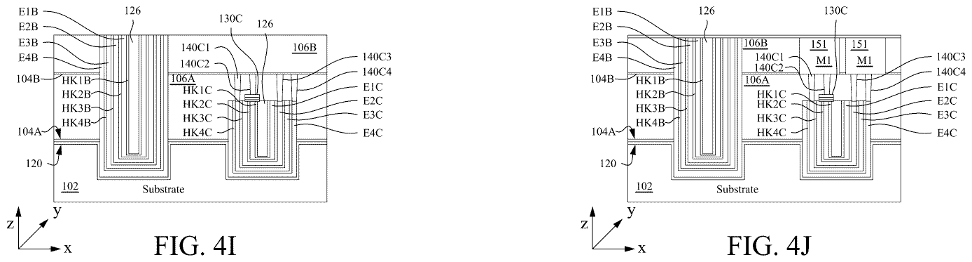

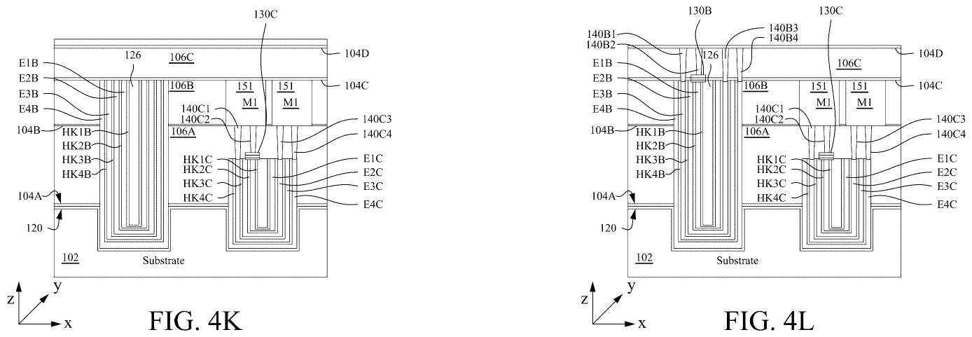

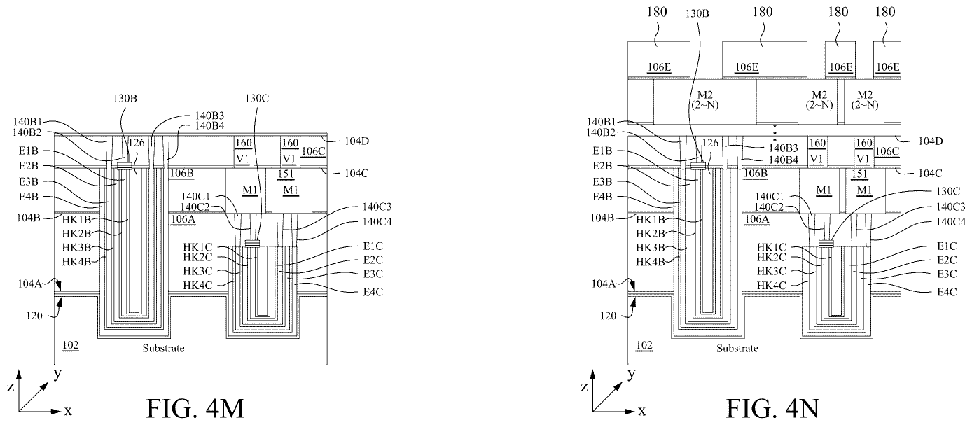

With reference to FIGS. 4A-4N, illustrated are various fabrication stages associated with the fabrication of an IC structure (Embodiment 1A) according to an example embodiment of the present disclosure.

FIG. 4A shows the forming on the substrate 102 the liner layer 120, the etch stop layer 104A and the intermetal dielectric layer 106A.

FIG. 4B shows the stage of etching the trench 110C at a trench depth TDC1 and depositing a trench liner 120 within the trench 110C.

FIG. 4C shows the stage of depositing electrodes E1C, E2C, E3C and E4C and HK (High K) dielectric material layers/regions HK1C, HK2C, HK3C and HK4C. A fill dielectric material 126 is deposited on the structure which provides a trench 110C dielectric core.

FIG. 4D shows the stage of removing a portion of the dielectric fill material 126, and polishing electrode E1C-E4C longitudinal ends and forming a BEOL (Back End of Line) transistor 130C, e.g., thin film transistor (TFT) on a single electrode longitudinal end.

FIG. 4E shows the next stage of depositing additional intermetal dielectric material 106A on the DTC structure.

FIG. 4F shows the next stage of depositing an etch stop layer 104B and subsequently depositing additional intermetal dielectric material 106B.

FIG. 4G shows the stage of forming electrical contacts 140C1, 140C2, 140C3 and 140C4 to the trench electrodes and BEOL transistor 130C gate, thereby completing the formation of a single DTC structure within the substrate 102.

FIG. 4H shows the stage of polishing the top surface, depositing additional intermetal dielectric material, and etching a second trench 110B to a depth of TDB1 within the substrate 102 and a depth of TDB2 within the dielectric material 106A and 106B.

FIG. 4I shows the stage of forming the second trench electrodes E1B, E2B, E3B and E4B, HK layers HK1B, HL2B, HK3B and HK4B between the electrodes, and filling the second trench 110B core with a dielectric filler material 126.

FIG. 4J shows the stage of patterning a metallization layer M1 for electrical connections to contacts 140C1, 140C2, 140C3 and 140C4, and forming etch stop layer 104C.

FIG. 4K shows the stage of polishing the etch stop layer 104C, depositing additional intermetal dielectric material 106C and forming another etch stop layer 104D.

FIG. 4L shows the formation of a BEOL transistor 130B, forming electrical contacts 140B1, 140B2, 140B3 and 140B4 to the second trench electrodes E1B, E2B, E3B and E4B.

FIG. 4M shows the formation of vias V1 160 electrically connected to the patterned metallization layer M1.

FIG. 4N shows the completed structure after forming another patterned metallization layer M(2 to N) electrically connected to the first DTC vias V1 160 and second DTC contacts 140B1, 140B2, 140B3 and 140B4.

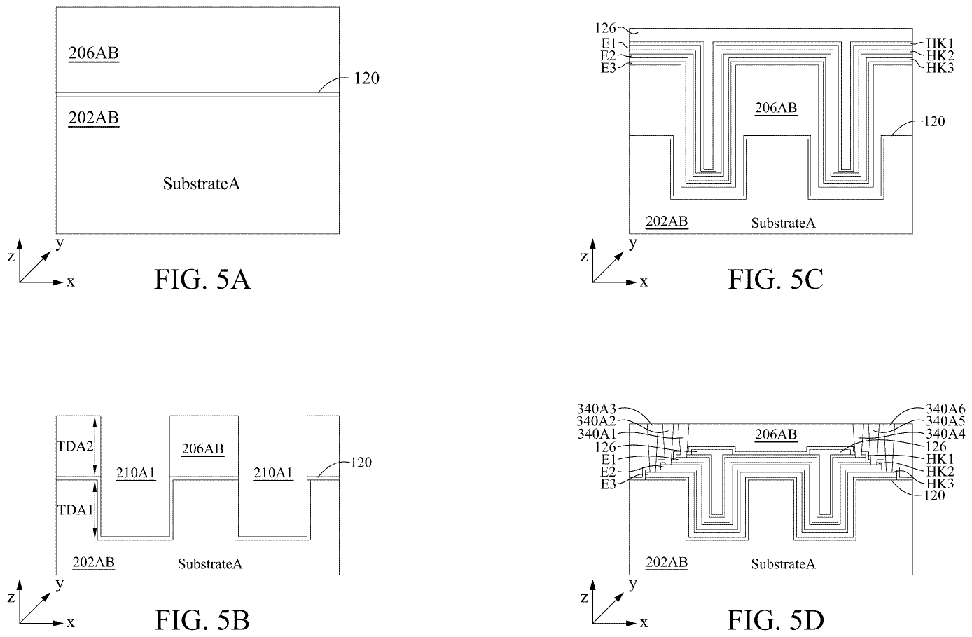

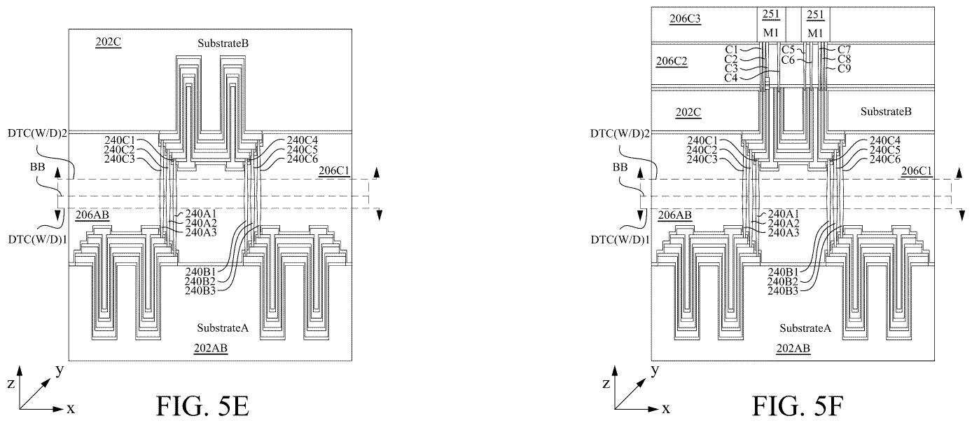

With reference to FIGS. 5A-5F, illustrated are various fabrication stages associated with the fabrication of an IC structure (Embodiment 2A) according to an example embodiment of the present disclosure, including a 2.5D-like formation process flow.

FIG. 5A shows forming on a substrate 202AB a trench line layer 120 and intermetal dielectric layer 206AB.

FIG. 5B shows the stage of etching a first and second trench, 210A1 and 210A2 respectively, and depositing additional liner material 120 in the trenches.

FIG. 5C shows the stage of gradually depositing electrode layers E1, E2, E3 and E4 and HK (High K) dielectric layers HK1, HK2, HK3 and HK4 in both the first trench 210A1 and second trench 219A2, and depositing fill dielectric material 126 in the first trench 210A1 and the second trench 210A2.

Subsequent to the steps performed as described with reference to FIG. 5C, continuous photolithography and etching processes are performed, ultimately completing the stepped structure depicted in FIG. 5D. FIG. 5D shows the stage of removing filled dielectric material 126, depositing an etch stop layer, depositing additional intermetal dielectric material 206AB, performing a patterning photoresist lithographic process (4 times) to form the electrode step structure shown, and forming and polishing the electrode metal contacts 340A1, 340A2, 340$3, 340A4, 340A5 and 340A6.

FIG. 5E shows the next stage including the bonding of the second DTC structure DTC(W/D)2 on substrate 202C, formed similarly, where the polished metal contacts are bonded to stack the first (DTC(W/D1) and second (DTC(W/D)2 DTC structures. Specifically, bonding electrical contact pairs 240A1 to 240C1, 240A2 to 240C2, 240A3 to 240C3, 240B1 to 240C4, 240B2 to 240C5, and 240B3 to 240C6.

FIG. 5F shows a final stage of the fabrication process including polishing the structure to expose the electrode metal contacts of the second DTC structure DTC(W/D)2, forming an etch stop layer 204E, depositing additional intermetal dielectric material 206C3, forming the metal contacts C1-C9 electrically connected to the second DTC structure electrodes and performing a patterned deposition process to form the metallization circuit layer M1.

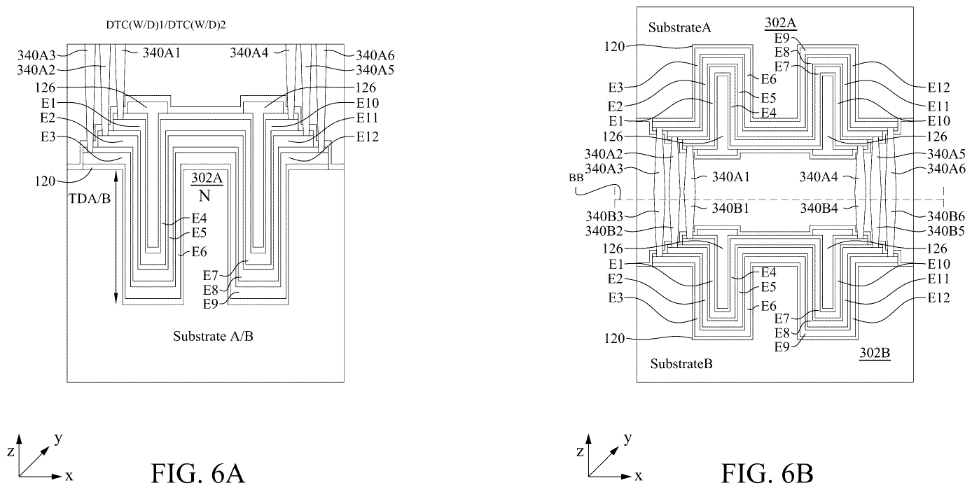

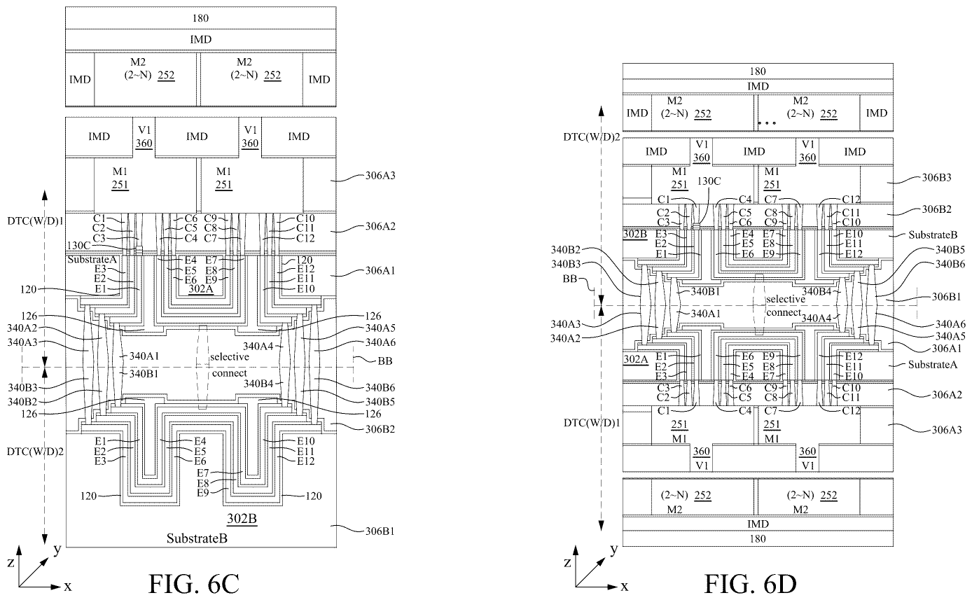

With reference to FIGS. 6A-6D, illustrated are various fabrication stages associated with the fabrication of an IC structure (Embodiment 3A) according to an example embodiment of the present disclosure, including a 3D-like process flow initially using two identical wafers, DTC(W/D)1 and DTC(W/D)2 after being polished.

FIG. 6A shows an initial stage of the two DTC wafers DTC(W/D)1 and DTC(W/D)2 after polishing (only one shown) and including trenches of depth TDA/B. FIG. 3A and the description of FIG. 3A provide further structural details of the structure shown.

FIG. 6B shows the bonding of the wafers DTC(W/D)1 and DTC(W/D)2 at or near bounding boundary BB by bonding of the metal contacts of each of the wafers. FIG. 3A and the description of FIG. 3A provide further structural details of the structure shown.

FIG. 6C shows the stage of polishing the structure to expose the electrodes of one of the wafers DTC(W/D1, depositing intermetal dielectric material, forming metal contacts to the electrodes of a top wafer trench using formed vias V1 360, and subsequently depositing intermetal dielectric material and patterned metallization layer circuits, as well as a passivation layer, the metal contacts and metallization layer circuit providing electrical connections of the resulting DTC 3D stacked structure on a first side. FIG. 3A and the description of FIG. 3A provide further structural details of the structure shown.

FIG. 6D shows, similar to FIG. 6C, the stage of polishing the structure to expose the electrodes of the other wafer DTC(W/D)2, depositing intermetal dielectric material, forming metal contacts to the electrodes of the top wafer DTC(W/D)2 trench using formed vias V1 360, and subsequently depositing intermetal dielectric material and patterned metallization layer circuits M2 252, as well as a passivation layer, the metal contacts and metallization layer circuit providing electrical connections of the resulting DTC 3D stacked structure on a second side. FIG. 3A and the description of FIG. 3A provide further structural details of the structure shown.

The diagrams shown above, illustrate the reduction of multiple photolithography and etching processes, as depicted in FIGS. 4A-4N, by simplifying it to be achieved with a single CMP process, according to an example embodiment. By using contacts to bond two wafers, a three-dimensional structure is formed, as shown in FIGS. 5A-5F and FIGS. 6A-6D. The final step involves grinding the backside to enable circuit connections on both sides, achieving a 3DIC structure, as depicted in FIGS. 6A-6D.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed DTC structures, devices, and methods of forming the same, provide a tunable DTC structure for integration in various IC which in turn may improve the performance and manufacturability of high performance ICs.

In the following, some further embodiments are described.

In a nonlimiting illustrative embodiment, a method of forming a deep trench stacked capacitor structure in a semiconductor substrate comprising: forming a first trench in a substrate, the first trench including a first trench bottom and a first trench plurality of sides; forming a first group of alternating electrode and dielectric layers in the first trench, the first group of alternating layers covering the first trench bottom and the first trench plurality of sides, and the first group of alternating layers including a first metallic electrode layer, a second metallic electrode layer and a first dielectric layer disposed between the first and second metallic electrode layers to form a first capacitor, each of the first and second metallic electrode layers including a first longitudinal end and a second longitudinal end; forming in the first trench a filler dielectric region in a center region of the trench, the filler dielectric region extending along a longitudinal length of the first trench and the filler dielectric region forming a core dielectric region of the first trench which is at least partially encased by the first group of alternating layers; forming on the first longitudinal end of the first metallic electrode layer a thin film transistor (TFT) structure including a gate region, a dielectric region and a semiconductor region operatively connected to the first metallic electrode layer, the TFT structure formed to control electrical conductivity from the TFT gate to the first metallic electrode layer by the application of a gate voltage to switch on and off a capacitance provided by the first capacitor; and forming a first metal contact on the TFT gate region and forming a second metal contact on the first longitudinal end of the second metallic electrode.

In another nonlimiting illustrative embodiment, a deep trench capacitor (DTC) structure comprising: a semiconductor substrate; a first trench formed in the substrate, the first trench including a first trench bottom and a first trench plurality of sides; a first group of alternating electrode and dielectric layers formed in the first trench, the first group of alternating layers covering the first trench bottom and the first trench plurality of sides, and the first group of alternating layers including a first metallic electrode layer, a second metallic electrode layer and a first dielectric layer disposed between the first and second metallic electrode layers to form a first capacitor, each of the first and second metallic electrode layers including a first longitudinal end and a second longitudinal end; a filler dielectric region forming in the first trench in a center region of the trench, the filler dielectric region extending along a longitudinal length of the first trench and the filler dielectric region forming a core dielectric region of the first trench which is at least partially encased by the first group of alternating layers; a thin film transistor (TFT) structure formed on the first longitudinal end of the first metallic electrode layer, the TFT structure including a gate region, a dielectric region and a semiconductor region operatively connected to the first metallic electrode layer, the TFT structure formed to control electrical conductivity from the TFT gate to the first metallic electrode layer by the application of a gate voltage to switch on and off a capacitance provided by the first capacitor; and a first metal contact formed on the TFT gate region and a second metal contact formed on the first longitudinal end of the second metallic electrode.

In another nonlimiting illustrative embodiment, a method of forming an integrated circuit (IC) including a stacked deep trench capacitor (DTC) structure comprising: forming a first deep trench capacitor structure in a first semiconductor substrate, the first deep trench capacitor structure including a plurality of planarized metal contacts electrically connected to a plurality of electrodes within a trench formed in the first substate, and the plurality of planarized metal contacts extending into an intermetal region formed on the first semiconductor substrate; forming a second deep trench capacitor structure in a second semiconductor substrate, the second deep trench capacitor structure including a plurality of planarized metal contacts electrically connected to a plurality of electrodes within a trench formed in the second substate, and the plurality of planarized metal contacts extending into an intermetal region formed on the second semiconductor substrate; bonding the first deep trench capacitor structure to the second deep trench capacitor structure by bonding each of the first deep trench capacitor structure plurality of planarized metal contacts to a respective each of the second deep trench capacitor structure plurality of planarized metal contacts, thereby electrically connecting the first deep trench capacitor structure and the second deep trench capacitor structure; and forming a first IC interconnection structure including a plurality of metal contacts electrically connected to the plurality of electrodes within the first deep trench capacitor structure to provide the integrated circuit (IC) including a stacked deep trench capacitor (DTC) structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first trench in a substrate, the first trench including a first trench bottom and a first trench plurality of sides;
forming a first group of alternating electrode and dielectric layers in the first trench, the first group of alternating layers covering the first trench bottom and the first trench plurality of sides, and the first group of alternating layers including a first metallic electrode layer, a second metallic electrode layer and a first dielectric layer disposed between the first and second metallic electrode layers to form a first capacitor, each of the first and second metallic electrode layers including a first longitudinal end and a second longitudinal end;
forming in the first trench a filler dielectric region in a center region of the trench, the filler dielectric region extending along a longitudinal length of the first trench and the filler dielectric region forming a core dielectric region of the first trench which is at least partially encased by the first group of alternating layers;
forming on the first longitudinal end of the first metallic electrode layer a thin film transistor (TFT) structure including a gate region, a dielectric region and a semiconductor region operatively connected to the first metallic electrode layer, the TFT structure formed to control electrical conductivity from the TFT gate to the first metallic electrode layer by the application of a gate voltage to switch on and off a capacitance provided by the first capacitor; and
forming a first metal contact on the TFT gate region and forming a second metal contact on the first longitudinal end of the second metallic electrode.

2. The method of claim 1, wherein forming the first group of alternating electrode and dielectric layers in the trench further comprises:
forming a second dielectric layer and a third metallic electrode, the second electric layer disposed between the second and third metallic electrode layers to form a second capacitor with a capacitance greater than the first capacitor, the third metallic electrode layer including a first longitudinal end and a second longitudinal end; and
forming a third metal contact on the first longitudinal end of the third metallic electrode.

3. The method of claim 1, further comprising:
operatively connecting the first and second metal contacts to an integrated circuit (IC) voltage output, the IC voltage output including a first voltage operatively applied to the first metal contact and a second voltage operatively applied to the second metal contact, the first voltage being greater than the second voltage.

4. The method of claim 1, further comprising:
forming a liner layer in the first trench prior to forming the first group of alternating electrode and dielectric layers in the trench.

5. The method of claim 1, further comprising:
forming a metallization layer circuit providing electrical connections to other deep trench capacitor structures operatively connected to the first trench first metal contact and the first trench second metal contact.

6. The method of claim 1, further comprising:
forming a second trench in the substrate, the second trench including a second trench bottom and a second trench plurality of sides, and the second trench separated from the first trench by the substrate;
forming a second group of alternating electrode and dielectric layers in the second trench, the second group of alternating layers covering the second trench bottom and the second trench plurality of sides, and the second group of alternating layers including a first metallic electrode layer, a second metallic electrode layer and a first dielectric layer disposed between the first and second metallic electrode layers to form a first capacitor, each of the first and second metallic electrode layers including a first longitudinal end and a second longitudinal end;
forming in the second trench a filler dielectric region in a center region of the second trench, the filler dielectric region extending along a longitudinal length of the second trench and the filler dielectric region forming a core dielectric region of the second trench which is at least partially encased by the second group of alternating layers; and
forming a first metal contact on the first longitudinal end of the first metal contact and forming a second metal contact on the first longitudinal end of the second metallic electrode.

7. The method of claim 6, further comprising:
forming a metallization layer circuit electrically connecting the first trench first metal contact and the second trench first metal contact, and electrically connecting the first trench second metal contact and the second trench second metal contact.

8. The method of claim 7, wherein the first trench has a first trench depth and the second trench has a second trench depth, the first trench depth different from the second trench depth.

9. A structure comprising:
a semiconductor substrate;
a first trench formed in the substrate, the first trench including a first trench bottom and a first trench plurality of sides;
a first group of alternating electrode and dielectric layers formed in the first trench, the first group of alternating layers covering the first trench bottom and the first trench plurality of sides, and the first group of alternating layers including a first metallic electrode layer, a second metallic electrode layer and a first dielectric layer disposed between the first and second metallic electrode layers to form a first capacitor, each of the first and second metallic electrode layers including a first longitudinal end and a second longitudinal end;
a filler dielectric region formed in the first trench in a center region of the trench, the filler dielectric region extending along a longitudinal length of the first trench and the filler dielectric region forming a core dielectric region of the first trench which is at least partially encased by the first group of alternating layers; and
a thin film transistor (TFT) structure formed on the first longitudinal end of the first metallic electrode layer, the TFT structure including a gate region, a dielectric region and a semiconductor region operatively connected to the first metallic electrode layer, the TFT structure formed to control electrical conductivity from the TFT gate to the first metallic electrode layer by the application of a gate voltage to switch on and off a capacitance provided by the first capacitor.

10. The device of claim 9, wherein the first group of alternating electrode and dielectric layers in the trench includes further comprises:
a first metal contact formed on the TFT gate region and a second metal contact formed on the first longitudinal end of the second metallic electrode;
a second dielectric layer and a third metallic electrode, the second electric layer disposed between the second and third metallic electrode layers to form a second capacitor with a capacitance greater than the first capacitor, the third metallic electrode layer including a first longitudinal end and a second longitudinal end; and
a third metal contact formed on the first longitudinal end of the third metallic electrode.

11. The device of claim 9, further comprising:
operatively connecting the first and second metal contacts to an integrated circuit (IC) voltage output, the IC voltage output including a first voltage operatively applied to the first metal contact and a second voltage operatively applied to the second metal contact, the first voltage being greater than the second voltage.

12. The device of claim 9, further comprising:
a liner layer formed in the first trench with the first group of alternating electrode and dielectric layers in the trench formed on the liner layer.

13. The device of claim 9, further comprising:
a metallization layer circuit providing electrical connections to other deep trench capacitor structures operatively connected to the first trench first metal contact and the first trench second metal contact.

14. The device of claim 9, further comprising:
a second trench formed in the substrate, the second trench including a second trench bottom and a second trench plurality of sides, and the second trench separated from the first trench by the substrate;
a second group of alternating electrode and dielectric layers formed in the second trench, the second group of alternating layers covering the second trench bottom and the second trench plurality of sides, and the second group of alternating layers including a first metallic electrode layer, a second metallic electrode layer and a first dielectric layer disposed between the first and second metallic electrode layers to form a first capacitor, each of the first and second metallic electrode layers including a first longitudinal end and a second longitudinal end;
a filler dielectric region formed in the second trench in a center region of the second trench, the filler dielectric region extending along a longitudinal length of the second trench and the filler dielectric region forming a core dielectric region of the second trench which is at least partially encased by the second group of alternating layers; and
a first metal contact formed on the first longitudinal end of the first metal contact and a second metal contact formed on the first longitudinal end of the second metallic electrode.

15. The device of claim 14, further comprising:
a metallization layer circuit electrically connecting the first trench first metal contact and the second trench first metal contact, and electrically connecting the first trench second metal contact and the second trench second metal contact.

16. The device of claim 15, wherein the first trench has a first trench depth and the second trench has a second trench depth, the first trench depth different from the second trench depth.

17. A method comprising:
forming a first deep trench capacitor structure in a first semiconductor substrate, the first deep trench capacitor structure including a plurality of planarized metal contacts electrically connected to a plurality of electrodes within a trench formed in the first substate, and the plurality of planarized metal contacts extending into an intermetal region formed on the first semiconductor substrate;
forming a second deep trench capacitor structure in a second semiconductor substrate, the second deep trench capacitor structure including a plurality of planarized metal contacts electrically connected to a plurality of electrodes within a trench formed in the second substate, and the plurality of planarized metal contacts extending into an intermetal region formed on the second semiconductor substrate;
bonding the first deep trench capacitor structure to the second deep trench capacitor structure by bonding each of the first deep trench capacitor structure plurality of planarized metal contacts to a respective each of the second deep trench capacitor structure plurality of planarized metal contacts, thereby electrically connecting the first deep trench capacitor structure and the second deep trench capacitor structure; and
forming a first IC interconnection structure including a plurality of metal contacts electrically connected to the plurality of electrodes within the first deep trench capacitor structure to provide an integrated circuit (IC) including a stacked deep trench capacitor (DTC) structure.

18. The method of claim 17, further comprising:
forming a first metallization layer circuit providing electrical connections to other deep trench capacitor structures operatively connected to the first IC interconnection structure.

19. The method of claim 17, further comprising:
forming a second IC interconnection structure including a plurality of metal contacts electrically connected to the plurality of electrodes within the second deep trench capacitor structure to provide the integrated circuit (IC) including a stacked deep trench capacitor (DTC) structure.

20. The method of claim 17, further comprising:
forming on a first longitudinal end of a first metallic electrode layer of the first deep trench capacitor structure a thin film transistor (TFT) structure including a gate region, a dielectric region and a semiconductor region operatively connected to the first metallic electrode layer, the TFT structure formed to control electrical conductivity from the TFT gate to the first metallic electrode layer by the application of a gate voltage to switch on and off a capacitance provided by a first capacitor provided by alternating electrode and dielectric layers in the first deep trench capacitor structure.
